(19) United States
(12) Patent Application Publication
(10) Pub. No.: US 2026/0136642 A1
(43) Pub. Date: May 14, 2026

(54) Threshold Voltage Tuning Using a Multiple Dipole Loop Process for Monolithic CFET Devices

(71) Applicant: Taiwan Semiconductor Manufacturing Company, Ltd., Hsin-Chu (TW)

(72) Inventors: Cheng-Ming LIN, Kaohsiung City (TW); Tsung-Kai CHIU, Hsinchu County (TW); Wei-Yen WOON, Taoyuan City (TW); Szuya LIAO, Zhubei Hsinchu (TW)

(21) Appl. No.: 19/177,157

(22) Filed: Apr. 11, 2025

Related U.S. Application Data
(60) Provisional application No. 63/719,867, filed on Nov. 13, 2024.

(51) Int. Cl. H10D 84/01; H10D 84/85

(52) U.S. Cl. CPC H10D 84/0181; H10D 84/0177; H10D 84/851; H10D 84/856

(57) ABSTRACT

The present disclosure provides a method that includes providing a substrate; forming active regions on the substrate, wherein the active regions include a plurality of first semiconductor layers and second semiconductor layers alternatively stacked; forming a gate dielectric layer on the active regions; forming a first dipole material M patterned on the gate dielectric layer of top FETs and bottom FETs; performing a first dipole process to the gate dielectric layer with a first temperature T1; forming a second dipole material M on the gate dielectric layer on the top FETs and absent from the gate dielectric layer of the bottom FETs; performing a second dipole process to the gate dielectric layer with a second temperature T2 less than T1 and X being different from M; and filling a work function metal material on the gate dielectric layer of both the bottom FETs and the top FETs.

### PRIORITY

This application claims the benefits of and priority to U.S. Provisional Application No. 63/719,867, filed Nov. 13, 2024, which is herein incorporated by reference in its entirety.

### BACKGROUND

The present disclosure relates to an integrated circuit (IC) structure and a method of making the same. Especially, the IC structure includes a transistor structure having multiple vertically stacked gate-all-around transistors, each of which includes multiple vertically stacked nanowires or nanosheets as channels. More specifically, the IC structure includes a complementary field-effect transistor (CFET) structure and the method of making the CFET. The CFET may include N-type FETs vertically over P-type FETs or P-type FETs vertically over the N-type FET. For advanced technology such as CFETS, multi threshold voltage (Vt) devices are necessary to provide high speed or low standby power devices. Existing structure and methods include varying metal gate thicknesses or metal gate materials to create multi Vt offerings. However, relying on metal gate thickness and different metal materials in advanced technologies such as CFETs becomes difficult due to critical dimension scaling. Therefore, while existing threshold voltage tuning for IC devices are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 illustrates a cross-sectional view of a CFET structure having multi Vt offerings, according to various aspects of the present disclosure.

FIG. 2A is a perspective view of the CFET structure, in portion or in entirety, according to various aspects of the present disclosure.

FIG. 2B is a cross-sectional view of the CFET structure, in portion or in entirety, according to various aspects of the present disclosure.

FIGS. 3A-3B is a flowchart of a method to form a CFET semiconductor device having multi Vt offerings, in portion or in entirety, according to various aspects of the present disclosure.

FIGS. 4-12 illustrate cross-sectional views of the IC structure having multi Vt offerings at intermediate stages of fabrication processes in accordance with the method of FIGS. 2A-2B according to an embodiment of the present disclosure.

FIG. 13 is a flowchart of a method to form a CFET semiconductor structure having multi Vt offerings, in portion or in entirety, according to various aspects of the present disclosure.

FIGS. 14A through 14G illustrates cross-sectional views of the CFET semiconductor structure at intermediate stages of fabrication processes according to some embodiments of the present disclosure.

FIGS. 15A and 15B illustrates tables of various dipole compositions and concentrations in the gate dielectric layers of bottom FETs and top FETs according to an embodiment of the present disclosure.

FIGS. 16A and 16B illustrates diagrams of the distributions of various dipole compositions and concentrations in the gate dielectric layers of bottom FETs and top FETs according to an embodiment of the present disclosure.

FIGS. 17A, 17B and 17C illustrates cross-sectional views of a CFET semiconductor structure, in portion, constructed according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure relates to an integrated circuit (IC) structure and a method of making the same. Especially, the IC structure includes a transistor structure having multiple vertically stacked gate-all-around transistors, each of which includes multiple vertically stacked nanowires or nanosheets as channels. More specifically, the IC structure includes a complementary field-effect transistor (CFET) structure and the method of making the CFET. The CFET may include N-type FETs (NFETs) vertically over P-type FETs (PFETs) or P-type FETs vertically over the N-type FET. Each of the NFETs and PFETs further includes multiple channels vertically stacked over.

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of IC structures (such as three-dimensional transistors) and processing and, for these advancements to be realized, similar developments in IC processing and manufacturing are needed. For example, device performance (such as device performance degradation associated with various defects) and fabrication cost of field-effect transistors become more challenging when device sizes continue to decrease, especially for CFET structure.

When CFET devices are formed by a monolithic process, an etching process is applied to metal for dual metal gates may attack the gate dielectric layer, such as a high-k (HK) dielectric material layer, and induce device degradation. Furthermore, when high thermal process and heavy dipole atom concentration is needed for ultralow threshold voltage applications, which may lead to degradation of contact resistance and channel mobility. The disclosed CFET structure and method making the same eliminate the metal etching and implements a dipole treatment with low thermal issues.

The present disclosure is generally related to semiconductor devices and the fabrication thereof, and more particularly to methods of fabricating field-effect transistors (FETs), such as fin-like FETs (FinFETs), gate-all-around FETs (GAA FETs), complimentary FETs (CFETs) and/or other FETs. Particularly, the semiconductor devices include CFETs and the method making the same. The method includes a procedure to form the semiconductor devices including CFETs by a monolithic process and a dipole treatment process tuned to achieve multiple threshold voltages in FETs and avoid metal gate etching and recessing.

The present disclosure relates to CFET semiconductor devices having multiple threshold voltage (Vt) offerings for optimized performance in targeted applications (e.g., high speed or low standby power devices). However, due to the complexity of a CFET structure and to address the CFET critical dimension limitations, integrating dipoles become more important for “volume-less” Vt tuning. That is, instead of increasing the volume dimension of a metal gate structure for Vt tuning, dipoles are driven into the gate structures without increasing the volume of the metal gate structure. For enhanced performance and device flexibility, a tunable N-type dipole (such as lanthanum oxide) and a tunable P-type dipole (such as zinc oxide) are combined with multi patterning on CFET for continuously variable Vt Tuning. The combination of multi-patterning (dipole patterning) and multi-annealing (dipole loops) on CFET with n-type and p-type specific dipoles offer volume-less multi-Vt devices that satisfy critical dimension limitations and provide large range of threshold voltages. For example, different CFET gate structures of the same size may be doped differently to have different threshold voltages. For another example, NFET and PFET gate regions of a same CFET may be doped differently to have different threshold voltages. Yet in another example, gate regions within a same NFET or PFET of a CFET may be doped differently from channel to channel, offering different threshold activation voltages for a single NFET or PFET.

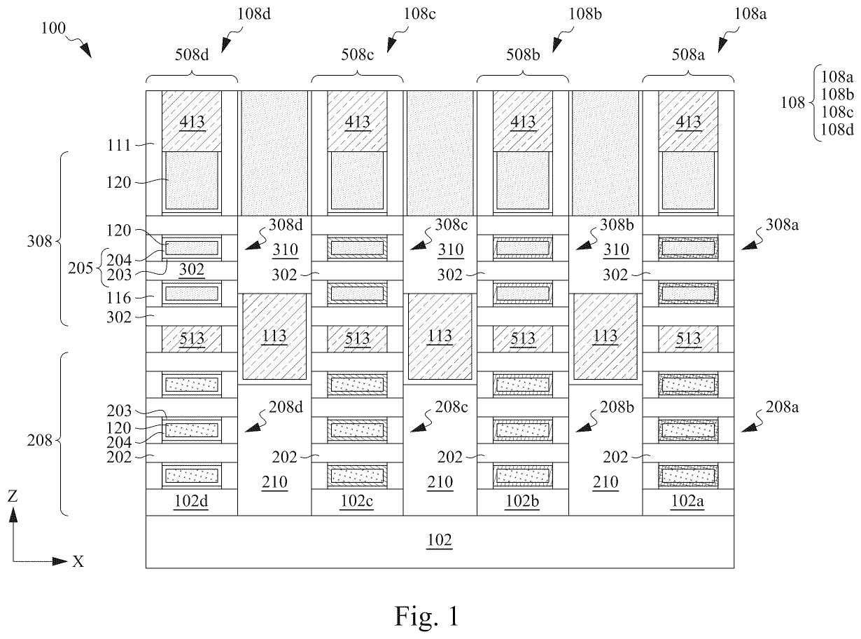

FIG. 1 illustrates a cross-sectional view of a monolithic CFET semiconductor device (or simply IC structure) 100 having multi Vt offerings. As will be explained in more detail below, the multi Vt offering is effectuated through iteratively doping respective gate dielectric layers 204 and/or 304 in different CFET gate regions 108. As an exemplary embodiment, FIG. 1 shows four CFET gate regions 108a, 108b, 108c, and 108d over respective channel regions 102a, 102b, 102c, and 102d protruding from a substrate 102. Stacks of semiconductor channels 202 and/or 302 are disposed over respective channel regions 102a, 102b, 102c, and 102d. In each of the CFET gate regions 108, the semiconductor channels 202/302 are wrapped around and interposed by respective CFET metal gate structures 508a, 508b, 508c, and 508d, each having a gate dielectric layer 205 and a metal gate electrode 120. A top portion of the metal gate electrode 120 is disposed over the topmost channels 302 of each stack.

Still referring to FIG. 1, the CFET gate regions 108 include NFET gate regions 308 over PFET gate regions 208. More specifically, each of the metal gate structures 508a-508d includes a NFET gate region 308 over a PFET gate region 208. For example, an NFET gate region 308a is over a PFET gate region 208a for the CFET metal gate structure 508a; an NFET gate region 308b is over a PFET gate region 208b for the CFET metal gate structure 508b; an NFET gate region 308c is over a PFET gate region 208c for the CFET metal gate structure 508c; and an NFET gate region 308d is over a PFET gate region 208d for the CFET metal gate structure 508d. The NFET gate regions 308 include gate dielectric layers 204 doped in various concentrations by a suitable dipole dopant, such as n-type dipoles, for reducing the threshold voltage of the NFET. The PFET gate regions 208 include gate dielectric layers 204 doped in various concentrations by a suitable dipole dopant for reducing the threshold voltage of the PFET. The gate dielectric layers in the NFET gate regions 308 surround semiconductor channels 302 to form NFETs, and the gate dielectric layers in the PFET gate regions 208 surround semiconductor channels 202 to form PFETs. Each of the respective gate dielectric layers 204 are surrounded by the metal gate electrode 120. Especially, a same type of dipole materials (such as n-type dipole materials) is used for both NFETs and PFETs but with different combinations of doping composition and dipole concentration to achieve tuning threshold voltages of NFETs and PFETs for different CFET devices; and the metal gate electrodes for both PFETs and NFETs includes a same type of work function metal, such as P-type work function metal. In some embodiments, dipole treatments use two n-type dipole materials, the metal gate electrodes for both PFETs and NFETs includes a same type of work function metal, such as P-type work function metal. In some embodiments, dipole treatments use two p-type dipole materials, the metal gate electrodes for both PFETs and NFETs includes a same type of work function metal, such as N-type work function metal.

Still referring to FIG. 1, the different dopant concentrations and compositions in the gate dielectric layers 204 for NFET gate regions 308a, 308b, 308c, and 308d arc illustratively shown by different density of a first pattern fill. For example, in the NFET gate region 308a, first n-type dipoles and second n-type dipoles are driven into the gate dielectric layers 204; in the NFET gate region 308b, the first n-type dipoles and the second n-type dipoles are driven into the gate dielectric layers 204 with different concentration; in the NFET gate region 308c, the second n-type dipoles are driven into the gate dielectric layers 204; and in the NFET gate region 308d, either no dipole treatment or with other different doping compositions and concentrations. Dipole treatments include multiple dipole treatment cycles (or dipole loops). Each dipole loop process involves annealing to selectively drive n-type dipole dopants into the gate dielectric layers 204 in one or more NFET gate regions to the exclusion of another one or more NFET gate regions. This is done through a dipole patterning process that masks certain CFET gate regions 108 before performing each dipole loop, as will explained below in more detail. In another example, in the PFET gate region 208a, the first n-type dipoles are driven into the gate dielectric layers 204; in the PFET gate region 208b, the first n-type dipoles are driven into the gate dielectric layers 204 with different concentration; in the PFET gate region 208c, no dipole treatment; and in the PFET gate region 208d, either no dipole treatment or a dipole treatment with different combinations of the dipole composition and concentration. Each dipole loop process involves annealing to selectively drive p-type dipole dopants into the gate dielectric layers 204 in one or more PFET gate regions to the exclusion of another one or more PFET gate regions. This is done through a dipole patterning process that masks certain CFET gate regions 208 before performing each dipole loop, as will explained below in more detail.

Still referring to FIG. 1, the monolithic CFET semiconductor device 100 includes CFET metal gate structures 508a, 508b, 508c, and 508d in the CFET gate regions 108a, 108b, 108c, and 108d, in which both PFETs and NFETs formed on a same semiconductor substrate. In each respective metal gate structure 508a-508d, a metal gate electrode 120 is filled in between semiconductor channels 202/302 in both the PFET and NFET gate regions 208 and 308. Due to the dipole loop processes, the gate dielectric layer 205 is characteristically changed but the dimensions remain. Accordingly, the dimensions of the metal gate electrode 120 across CFET metal gate structures 508a-508d remain the same. That is, gate dimensions are not changed to vary Vt across different CFET devices. For example, a thickness of a portion of the metal gate electrode 120 wrapping around a semiconductor channel 202/302 for a high Vt CFET is substantially the same as a thickness of a portion of the metal gate electrode 120 wrapping around a semiconductor channel 202/302 for a low Vt CFET. As shown in FIG. 1, the thickness of the wrapping portions of metal gate electrode 120 across the CFET metal gate structures 508a-508d are the same. Further, a same metal fill material for the metal gate electrode 120 may be used for both the PFET and NFET gate regions 208 and 308. This is because no p-type and/or n-type specific metal is needed since the respective gate dielectric layers 204 are already doped with specific dipoles through the dipole loop processes.

Although FIG. 1 shows an increasing gradient of dipole dopant concentration in the gate dielectric layers 204 from left to right (i.e., from the CFET metal gate structures 508d to the CFET metal gate structures 508a), the present disclosure is not limited thereto. Note that gate dielectric layer 205 may include an interfacial layer 203 and a high-k dielectric layer 204, collectively referred to as gate dielectric layer 205, the details of the gate dielectric layer will be further described later. Depending on the dipole patterning process, different combinations of dipole dopant compositions and concentrations are possible from one CFET gate structure to another. Further, although FIG. 1 is described such that within a same CFET metal gate structure (e.g., 508a), the respective PFET and NFET gate regions (e.g., 208a and 308a) have a dipole process performed, the present disclosure is not limited thereto. Depending on the dipole loop process, different combinations of dipole dopant compositions and concentrations between PFET and CFET gate regions of a same CFET is also possible. Even further, although FIG. 1 shows NFET gate regions 308 over PFET gate regions 208 for a CFET device where the top device is an NFET and the bottom device is a PFET, the present disclosure is not limited thereto. Aspects of the present disclosure may equally apply to CFET devices where the top devices are PFETs and the bottom devices are NFETs where PFET gate regions 208 are over the NFET gate regions 308. Additional features not described with respect to FIG. 1 will be made apparent by following figures when describing the formation of a monolithic CFET semiconductor device 100.

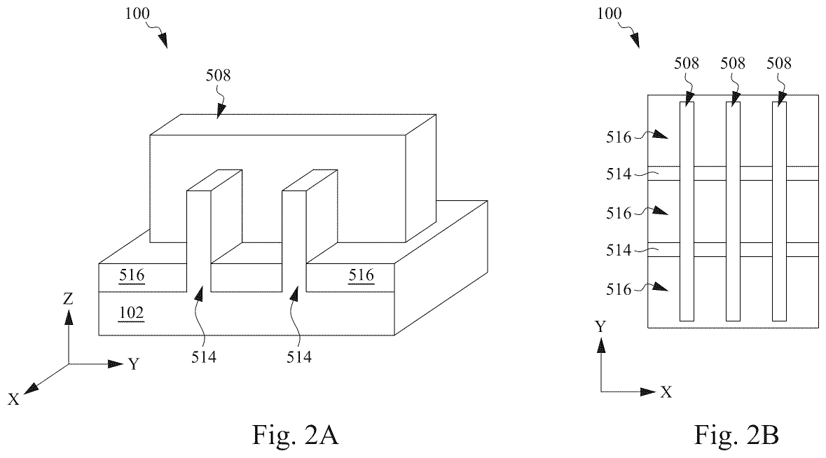

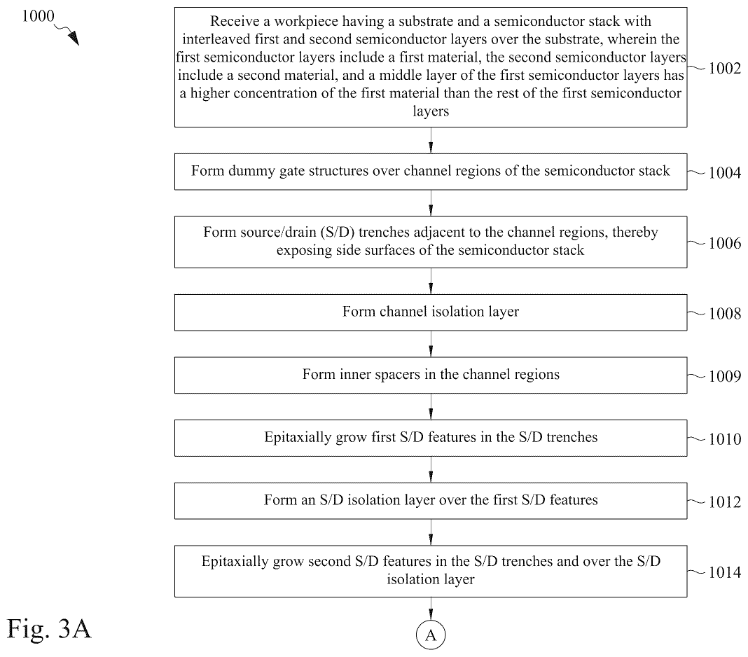

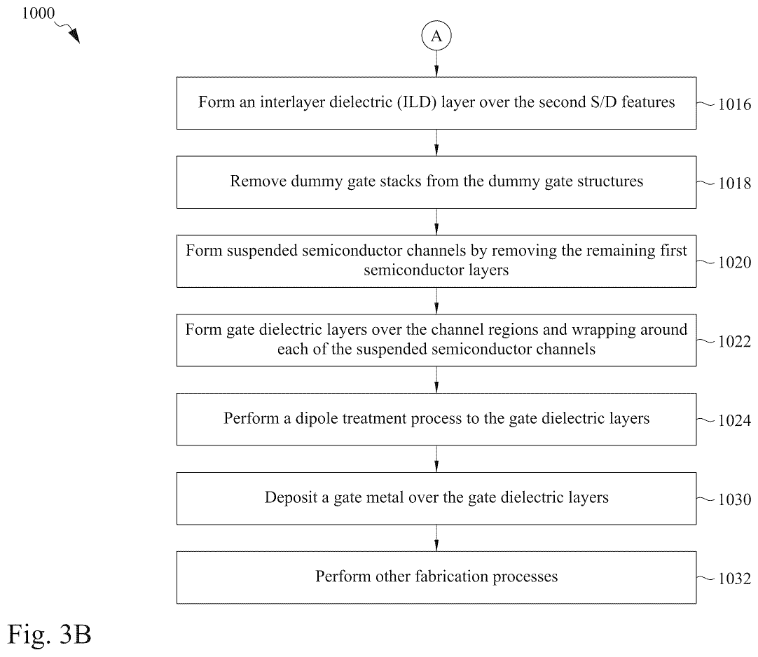

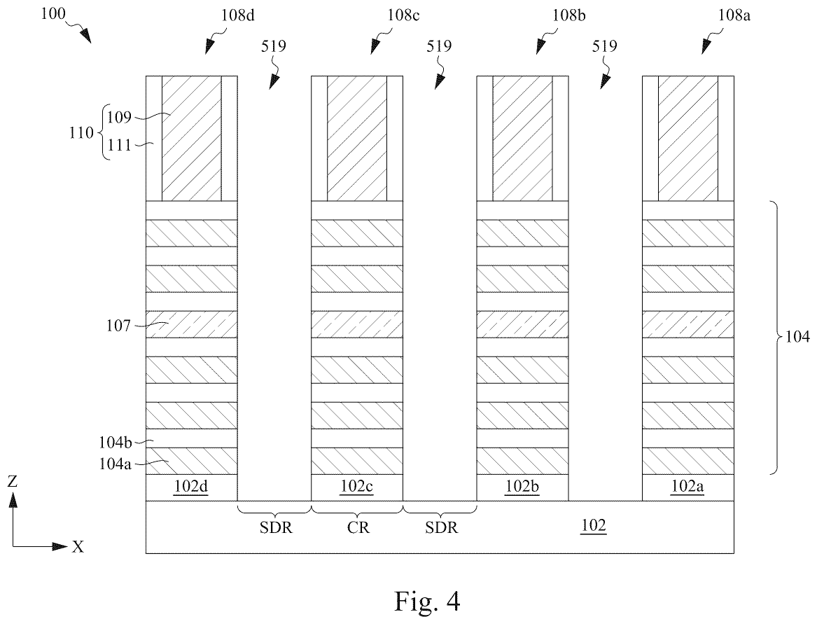

FIG. 2A is a perspective view; and FIG. 2B is a sectional view of the CFET semiconductor device 100, in portion, constructed according to some embodiments. FIGS. 3A-3B is a flowchart of a method 1000 to form a monolithic CFET semiconductor device 100 having multiple Vt offerings, in portion or in entirety, according to various aspects of the present disclosure. The method 1000 is briefly described below with reference to FIGS. 1, 2A-2B, 3A-3B, other figures including FIGS. 4 through 12.

At operation 1002, the method 1000 receives or is provided with a workpiece having a substrate 102 and a semiconductor stack with interleaved first and second semiconductor layers over the substrate. The first semiconductor layers include a first material, the second semiconductor layers include a second material, and a middle layer of the first semiconductor layers has a higher concentration of the first material than the rest of the first semiconductor layers. The first and second semiconductor layers are patterned to form one or more semiconductor stack as active regions, such as fin active regions.

The substrate 102 may include an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor, such as SiGe, GaAsP, AlInAs, AlGaAs, GaInAs, GaInP, GaInAsP, and/or other suitable materials. The substrate 102 may be a single-layer material having a uniform composition. Alternatively, the substrate 102 may include multiple material layers having similar or different compositions suitable for IC device manufacturing. In one example, the substrate 102 may be a silicon-on-insulator (SOI) substrate having a silicon layer formed on a silicon oxide layer. In another example, the substrate 102 may include a conductive layer, a semiconductor layer, a dielectric layer, other layers, or combinations thereof.

In some embodiments where the substrate 102 includes various doped regions, such as doped wells and source/drain regions, disposed in or on the substrate 102. The doped regions may be doped with p-type dopants, such as phosphorus or arsenic, and/or n-type dopants, such as boron or BF₂, depending on design requirements. The doped regions may be directly formed on the substrate 102 (such as a p-well structure, an n-well structure, or a dual-well structure) or using a raised structure (such as an epitaxial S/D feature). Doped regions may be formed by implantation of dopant atoms, in-situ doped epitaxial growth, diffusion, and/or other suitable techniques.

The operation 1002 further includes patterning the semiconductor stack to form active regions 514 and forming isolation structures 516 to surround each active region and isolate the active regions 514 from each other. Each active regions 514 may be suitable for providing an n-type FET or a p-type FET. In some embodiments, the semiconductor active regions 514 as illustrated herein may be suitable for providing FinFETs, i.e., p-type on bottom portion or n-type on top portion. This configuration is for illustrative purposes only and is not intended to be limiting. The active regions 514 may be fabricated using suitable processes including photolithography and etch processes. The photolithography process may include forming a photoresist layer (or resist) overlying the substrate 102, exposing the resist to a pattern, performing post-exposure bake processes, and developing the resist to form a masking element (not shown) including the resist. The masking element is then used for etching recesses into the substrate 102, leaving the active regions 514 on the substrate 102. The etching process may include dry etching, wet etching, reactive ion etching (RIE), and/or other suitable processes.

Numerous other embodiments of methods for forming the active regions 514 may be suitable. For example, the active regions 514 may be patterned using double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the active regions 514.

The isolation structures 516 are surrounding various active regions 514 and separate the active regions 514 one from another. The isolation structures 516 may include silicon oxide, silicon nitride, silicon oxynitride, fluoride-doped silicate glass (FSG), a low-k dielectric material, and/or other suitable materials. The isolation structures 516 may include shallow trench isolation (STI) features. In one embodiment, the isolation structures 516 are formed by etching trenches in the substrate 102 during the formation of the active regions 514. The trenches may then be filled with one or more dielectric material described above by a deposition process, followed by a chemical mechanical planarization (CMP) process. The isolation structures 516 may be subsequently recessed, such as selective etching, such that a top surface of the isolation structures 516 is below a top surface of the active regions 514, defining the active regions 514 protruding above the isolation structure 516 with a height Hr for optimized coupling between the gate electrode and the channel. In some embodiments, the height Hr of the active regions 514 ranges between 40 nm and 80 nm. Other isolation structure such as field oxide, local oxidation of silicon (LOCOS), and/or other suitable structures may also be implemented as the isolation structures 516. Alternatively, the isolation structures 516 may include a multi-layer structure, for example, having one or more thermal oxide liner layers. The isolation structures 516 may be deposited by any suitable method, such as chemical vapor deposition (CVD), flowable CVD (FCVD), spin-on-glass (SOG), high-density plasma CVD (HDPCVD), high aspect ratio process (HARP), other suitable methods, or combinations thereof.

At operation 1004, the method 1000 forms dummy gate structures over channel regions of the semiconductor stack. The dummy gate structures include gate spacers and dummy gate stacks. In some embodiments, each dummy gate stack serves as a placeholder for subsequently forming a high-k metal gate structure (HKMG; where “high-k” refers to a dielectric material with a dielectric constant greater than that of thermal silicon dioxide, which is about 3.9). The dummy gate stack may include a dummy gate electrode and various other material layers. In some embodiments, the dummy gate electrode includes polysilicon. In the depicted embodiment, the dummy gate stack may include a dielectric layer disposed between the active regions 514 and the dummy gate electrode as an interfacial layer to the dummy gate stack. In some embodiments, the dummy gate stack is formed by deposition and a patterning process. The patterning process further includes photolithography process and etching. In the present embodiment, a hard mask is further used in the patterning process to form the dummy gate stack. As will be discussed in detail below, the dummy gate stack is replaced with the HKMG during a gate replacement process after other components (e.g., the S/D features) of the semiconductor structure 100 are fabricated. Various material layers of the dummy gate stack may be formed by any suitable process, such as CVD, PVD, ALD, other suitable processes, or combinations thereof. In some embodiments, the dummy gate stacks are formed by a suitable procedure, such as a procedure that includes depositing various gate material including hard mask; and patterning the gate materials by a photolithography process and etching. The operation 1004 also includes forming a gate spacer layer (or simply a spacer layer or gate spacers) on the sidewalls of the dummy gate stack. The spacer layer is formed by deposition and anisotropic etching. The spacer layer may include multiple films of different composition. In some embodiments, the spacer layer includes a first spacer layer of silicon oxide and a second spacer layer of silicon nitride disposed on the first spacer layer.

At operation 1006, the method 1000 forms source/drain (S/D) trenches adjacent to the channel regions, thereby exposing side surfaces of the semiconductor stack within a source/drain (S/D) region. In some embodiments, the method 1000 forms the S/D trenches by a suitable etching process, such as a dry etching process, a wet etching process, an RIE process, or a combination thereof. In some embodiments, the method 1000 selectively removes the portions of the active regions 514 within the S/D regions without etching or substantially etching portions of the spacer layers formed on sidewalls of the dummy gate stacks. The etching process at operation 1006 may implement a dry etching process using an etchant including a bromine-containing gas (e.g., HBr and/or CHBR₃), a fluorine-containing gas (e.g., CF₄, SF₆, CH₂F₂, CHF₃, and/or C₂F₆), other suitable gases, or combinations thereof. The extent of which the active regions is removed may be controlled by adjusting the duration of the etching process.

At operation 1008, the method 1000 form a channel isolation layer 513. The channel isolation layer 513 is formed between the top channels and bottom channels to provide isolation therebetween. The channel isolation layer 513 is formed by any suitable method. In some embodiments, the formation of the channel isolation layer 513 includes performing a selective etching process to remove the middle layer in the semiconductor stack, resulting in gaps between the bottom channels and top channels; refilling one or more dielectric material by deposition (such as CVD, other suitable deposition method or a combination thereof), and then performing a dry etching process to remove the excessive portion deposited in the S/D trenches. In an alternative embodiment, the channel isolation layer 513 may be formed at a later stage, such as be formed after the dummy gates are removed and before the metal gates (or HKMG) are formed. In this case, the middle layer is selectively removed; a dielectric layer is formed therein by deposition; and a dry etch may be further applied to remove the excessive portions of the deposited dielectric material.

With respect to selectively etching the middle layer 107, various etching parameters can be tuned such as etchant composition, etching temperature, etching solution concentration, etching time, etching pressure, source power, RF bias voltage, RF bias power, etchant flow rate, other suitable etching parameters, or combinations thereof. For example, an etchant is selected to etch the material of the middle layer 107 (e.g., highest concentration of germanium) at a higher rate than the semiconductor layers 104a (e.g., middle concentration of germanium). The etching process is a dry etching process, a wet etching process, other suitable etching process, or combinations thereof. In some embodiments, a dry etching process (such as an RIE process) utilizes a fluorine-containing gas (for example, SF6) to selectively etch the semiconductor layers. In some embodiments, a ratio of the fluorine-containing gas to an oxygen-containing gas (for example, O2), an etching temperature, and/or an RF power may be tuned to selectively etch silicon germanium (or silicon). In some embodiments, a wet etching process is performed with an etching solution that includes ammonium hydroxide (NH4OH) and water (H2O) to selectively etch the germanium-containing semiconductor layers. In some embodiments, a chemical vapor phase etching process using hydrochloric acid (HCl) is used.

At operation 1009, the method 1000 form inner spacers 116 underlying the gate spacer 111 on the sidewall of the dummy gate stack 109. The inner spacers 116 are formed vertically between the adjacent first semiconductor layers. The operation 1009 may include laterally etching; deposition; and anisotropic etching.

At operation 1010, the method 1000 epitaxially grows first S/D features (or bottom S/D features) 210 in the S/D trenches. The first S/D feature 210 may include multiple epitaxial semiconductor layers, such as a first semiconductor layer and a second semiconductor layer on the first semiconductor layer. In some embodiments, the first and second semiconductor layers differ in amount of dopant included therein. In some examples, the amount of dopant included in the first semiconductor layer is less than that included in the second semiconductor layer, to minimize potential leak currents and reduce the contact resistance. The dopant is in-situ introduced into the S/D feature 210 during the selective epitaxial growth. In some embodiments, the first and second semiconductor layers differ in composition to provide other advantages, such as strain effect to enhance the carrier mobility and the transistor speed. For example, the first and second semiconductor layers include silicon and silicon germanium, respectively, or vice versa, depending on the transistor types.

The first S/D feature 210 may be formed by any suitable method, such as MBE, MOCVD, other suitable epitaxial growth processes, or combinations thereof. The S/D feature 210 may be suitable for a p-type FinFET device (e.g., a p-type epitaxial material) or alternatively, an n-type FinFET device (e.g., an n-type epitaxial material). The p-type epitaxial material may include one or more epitaxial layers of silicon germanium (epi SiGe), where the silicon germanium is doped with a p-type dopant such as boron, germanium, indium, and/or other p-type dopants. The n-type epitaxial material may include one or more epitaxial layers of silicon (epi Si) or silicon carbon (epi SiC), where the silicon or silicon carbon is doped with an n-type dopant such as arsenic, phosphorus, and/or other n-type dopants. The formation of the first S/D features 210 may further include etching to recess the semiconductor layers so to be below the channel isolation layer.

At operation 1012, the method 1000 forms an S/D isolation layer 513 over the first S/D features. The S/D isolation layer 513 includes one or more dielectric material to provide isolation between the bottom S/D features 210 and the top S/D features 310 to be formed. The S/D isolation layer 513 can be formed by any suitable method, such as a method that includes bottom-up deposition. In another example, the method includes deposition. CMP, and etching to recess. In yet another example, the method includes deposition to form a thin dielectric layer; performing a tiled ion treatment to treat the sidewall portions of the deposited dielectric layer; and performing a selective etching process to remove the treated portion of the dielectric layer.

At operation 1014, the method 1000 epitaxially grows second S/D features (or top S/D features) 310 in the S/D trenches and over the S/D isolation layer 513. The S/D feature 310 may be formed by any suitable method, such as MBE, MOCVD, other suitable epitaxial growth processes, or combinations thereof. The S/D feature 310 may be suitable for an n-type FinFET device (e.g., an n-type epitaxial material) or alternatively p-type FinFET device (e.g., a p-type epitaxial material). The n-type epitaxial material may include one or more epitaxial layers of silicon (epi Si) or silicon carbon (epi SiC), where the silicon or silicon carbon is doped with an n-type dopant such as arsenic, phosphorus, and/or other n-type dopants.

At operation 1016, the method 1000 forms an interlayer dielectric (ILD) layer 413 over the second S/D features to provide isolation functions among various conductive features. The ILD layer 413 may be formed by deposition and CMP. The ILD layer includes one or more dielectric material, such as silicon oxide, tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), low-k dielectric material or other suitable dielectric material. In various embodiments, the ILD layer 413 is deposited by CVD, HDPCVD, sub-atmospheric CVD (SACVD), HARP, a flowable CVD (FCVD), and/or a spin-on process. In some embodiments, forming the ILD layer 413 further includes performing a CMP process to planarize a top surface, such that the top surfaces of the dummy gate stacks are exposed. In some embodiments, a bottom contact etch-stop layer (BCESL) is deposited between the ILD layer and the substrate 102 with a composition different from that of the ILD layer, such as silicon nitride, to achieve etch selectivity.

At operation 1018, the method 1000 removes dummy gate stacks from the dummy gate structures by etch, resulting in gate trenches in the ILD layer. The operation 1018 may additionally include patterning with photolithography process. Forming the gate trenches may include one or more etching processes that are selective to the materials included in the dummy gate stacks (e.g., polysilicon included in the dummy gate electrodes). The etching processes may include dry etching, wet etching, RIE, or other suitable etching methods, or combinations thereof.

At operation 1022, the method 1000 forms suspended semiconductor channels 202, 302 by removing the remaining first semiconductor layers. This operation is also referred to as a channel release process.

At operation 1024, the method 1000 forms gate dielectric layers 204 over the channel regions and wrapping around each of the suspended semiconductor channels 202, 302. In some embodiments, the gate dielectric layers include an interfacial layer 203, such as a silicon oxide layer and a high-k dielectric layer 204. The high-k dielectric material layer 204 may include one or more high-k dielectric materials (or one or more layers of high-k dielectric materials), such as hafnium silicon oxide (HfSiO), hafnium oxide (HfO₂), alumina (Al₂O₃), zirconium oxide (ZrO₂), lanthanum oxide (La₂O₃), titanium oxide (TiO₂), yttrium oxide (Y₂O₃), strontium titanate (SrTiO₃), or a combination thereof.

At operation 1026, the method 1000 performs a dipole treatment process to the gate dielectric layers 205. As described above, the dipole treatment process is designed according to various embodiments of the present disclosure to eliminate metal etch and tune CFET devices with various threshold voltages. That is, instead of increasing the volume dimension of a metal gate structure for Vt tuning, dipoles are driven into the gate structures without increasing the volume of the metal gate structure. For enhanced performance and device flexibility, a tunable N-type dipole (such as lanthanum oxide) and a tunable P-type dipole (such as zinc oxide) are combined with multi patterning on CFET for continuously variable Vt Tuning. The combination of multi-patterning (dipole patterning) and multi-annealing (dipole loops) on CFET with n-type and p-type specific dipoles offer volume-less multi-Vt devices that satisfy critical dimension limitations and provide large range of threshold voltages. For example, different CFET gate structures of the same size may be doped differently to have different threshold voltages. For another example, NFET and PFET gate regions of a same CFET may be doped differently to have different threshold voltages. Yet in another example, gate regions within a same NFET or PFET of a CFET may be doped differently from channel to channel, offering different threshold activation voltages for a single NFET or PFET. The dipole treatment process will be further described in detail with reference to other figures.

At operation 1030, the method 1000 forms gate electrodes 120. The gate electrodes 120 for both PFETs and NFETs include only one type of work function metal. In the present embodiments, the dipole treatment process adopts only n-type dipole material, the gate electrodes 120 include p-type work function metal, such as titanium nitride, tantalum nitride, tungsten nitride, other suitable p-type work function metal or a combination thereof. In alternative embodiments, the dipole treatment process may adopt only p-type dipole material, the gate electrodes 120 include n-type work function metal, such as: tantalum (Ta); tantalum aluminum (TiAl), TiAlC, TiAlO and TiAlN, other suitable n-type work function metal or a combination thereof. The gate electrodes 120 may further include a suitable fill metal, such as copper, on the p-type work function metal.

The method 1000 may include other operations 1032 before, during and after various operations described above. For example, the method 1000 includes forming an interconnect structure with various conductive features to coupled CFETs and other devices formed on the substrate 102 into an integrated circuit. The interconnect structure includes metal lines distributed in multiple metal layers; contacts to vertically connect devices to metal lines; and vias to vertically connect metal lines in the adjacent metal layers. The method 1000 may further includes forming a passivation structure on the interconnect structure. The passivation structure provides sealing effect to protect the integrated circuit from the environment, such as moisture; provides a redistribution layer to redistribute the bonding structure; and provides the bonding structure to couples the interconnect structure to the packaging, such as printed circuit board.

The method 1000 may perform further steps to complete fabrication of the monolithic CFET device 100. Additional processing is contemplated by the present disclosure. Additional operations can be provided before, during, and after method 1000, and some of the operations described can be moved, replaced, or eliminated for additional embodiments of method 1000.

FIGS. 4-12 illustrate cross-sectional views of a monolithic CFET semiconductor device (or IC structure) 100 having multi Vt offerings at intermediate stages of fabrication and processed in accordance with the method 1000 of FIGS. 3A-3B. The IC structure 100 may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random-access memory (NVRAM), a flash memory, an electrically erasable programmable read only memory (EEPROM), an electrically programmable read-only memory (EPROM), other suitable memory type, or combinations thereof.

As shown in FIG. 4 and referring to operation 1002, the method 1000 receives or is provided with a workpiece having a substrate 102 and a semiconductor stack 104 with interleaved first and second semiconductor layers 104a and 104b over the substrate 102. The substrate 102 may be a silicon (Si) substrate, or a substrate having other semiconductor materials such as germanium (Ge), silicon carbide (SIC), silicon germanium (SiGe), or diamond. The semiconductor stack 104 may also be referred to as active regions that extend lengthwise along the x direction. Additional semiconductor stacks 104 may be formed in parallel along the y direction, and the semiconductor stacks 104 are separated from each other by an isolation structure such as a shallow trench isolation (STI) structure (not shown).

The first semiconductor layers 104a have a different material composition than the second semiconductor layers 104b to achieve etch selectivity. For example, each of the first semiconductor layers 104a is made of silicon germanium and each of the second semiconductor layers 104b is made of silicon. Note that the first semiconductor layers 104a include a middle layer 107 that has a different concentration makeup than the rest of the first semiconductor layers 104a. For example, the middle layer 107 is made of silicon germanium but has a greater concentration of germanium than the rest of the first semiconductor layers 104a. In furtherance of the example, the first semiconductor layers 104a are SiGe layers with germanium concentration ranging between 20% and 25% (atomic percentage), and the middle layer 107 is a silicon germanium layer with germanium concentration greater than 30% (atomic percentage), such as ranging between 40% and 60%. This allows for selective etching of the middle layer 107 in a later process step, where the middle layer 107 is replaced with a channel isolation layer to separate a top device from a bottom device of the CFET device 100. Note that the middle layer 107 does not necessarily have to be in the exact middle to separate a top device from a bottom device. This layer may be closer to the top of the stack or closer to the bottom of the stack, and as such, it is possible that the bottom device will have more or less semiconductor channels than the top device. In an embodiment shown in FIG. 4, the first semiconductor layers 104a include a first material (i.e., germanium), the second semiconductor layers 104b include a second material (i.e., silicon), and a middle layer 107 of the first semiconductor layers 104a has a higher concentration of the first material (i.e., germanium) than the rest of the first semiconductor layers 104a. The second semiconductor layers 104b may be of a same material composition as the substrate 102. The operation 1002 also includes forming active regions and isolation structures as described above.

Still referring to FIG. 4, the method 1000 at operation 1004 forms dummy gate structures 110 over channel regions CR of the semiconductor stack 104. The channel regions CR include channel regions 102a-102d that are part of the substrate 102. Each of the dummy gate structures 110 includes a dummy gate stack 109 and gate spacers 111 over sidewalls of the dummy gate stack 109. The dummy gate stack 109 may be made of polysilicon and the gate spacers 111 may be made of silicon oxide, silicon nitride, silicon oxycarbide, silicon oxycarbonitride, silicon carbonitride, metal nitride, or a suitable dielectric material.

Still referring to FIG. 4, the method 1000 at operation 1006 forms source/drain (S/D) trenches 519 in S/D regions SDR adjacent to the channel regions CR, thereby exposing side surfaces of the semiconductor stack 104. The S/D trenches 519 may be formed by a dry etching process, a wet etching process, other suitable etching process, or combinations thereof. In some embodiments, the etching process is a multi-step etch process. For example, the etching process may include alternative etchants to separately and alternately remove first semiconductor layers 104a and semiconductor layers 104b. In some embodiments, parameters of the etching process are configured to selectively etch the semiconductor stack 104 with minimal (to no) etching of dummy gate structures 110 (i.e., dummy gate stacks 109 and gate spacers 111). In some embodiments, a lithography process is performed to form a patterned mask layer that covers dummy gate structures 110 and/or portions of an isolation structure between semiconductor stacks 104, and the etching process uses the patterned mask layer as an etch mask when forming the S/D trenches 519. Note that the etching process may also etch slightly into the substrate 102. That is, when forming the S/D trenches 519, the substrate 102 may be recessed to form protruding portions that define the channel regions 102a, 102b, 102c, and 102d.

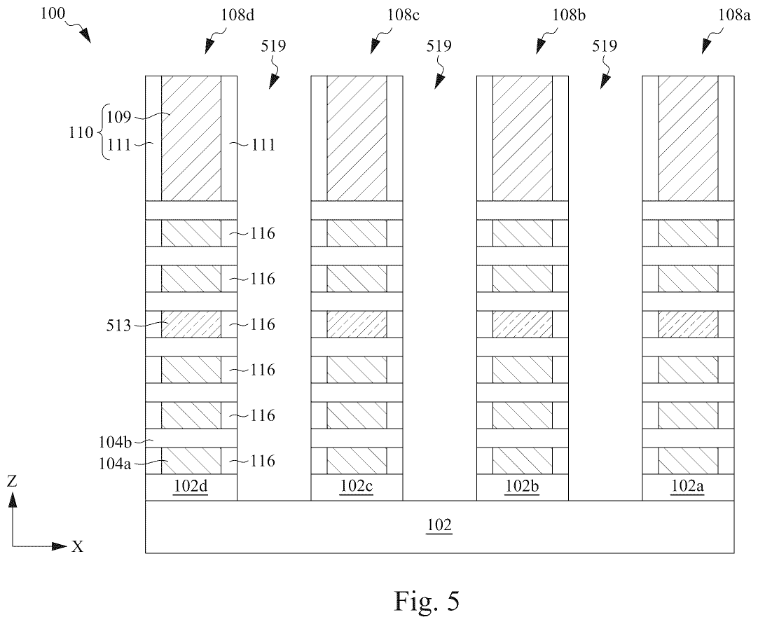

Now referring to FIG. 5, In some embodiments, the method 1000 includes an operation 1008 to form the channel isolation layer 513 before the formation of the inner spacers 116. The formation of the channel isolation layer 513 includes selective etching the middle layer 107, resulting in gaps between the bottom channels and top channels; depositing one or more dielectric material; and dry etching to remove excessive portions in the S/D trenches 519.

Still referring to FIG. 5, the method 1000 at operation 1009 forms inner spacers 116 in the channel regions CR along sidewalls of the first semiconductor layers 104a by any suitable process. For example, a side etch process is first performed to selectively etch sidewalls of the first semiconductor layers 104a without etching (or substantially etching) the second semiconductor layers 104b. In other words, the side etch process is configured to laterally etch (e.g., along the x direction) first semiconductor layers 104a, thereby reducing a length of first semiconductor layers 104a along the x direction. The side etch process is a dry etching process, a wet etching process, other suitable etching process, or combinations thereof. After the side etch process is performed, air gaps are formed under each of the second semiconductor layers 104b. Then, as shown in FIG. 5, inner spacers 116 are formed in each of the air gaps. The inner spacers 116 are disposed directly below the gate spacers 111, and they may be substantially vertically aligned with the gate spacers 111 along the z direction.

The inner spacers 116 may be formed by a spacer deposition process and a spacer etching process. For example, a spacer deposition process is performed to form a spacer layer over the dummy gate structures 110 and over features defining the S/D trenches 519 (e.g., semiconductor layers 104a, semiconductor layers 104b, and substrate 102). The spacer deposition process may include processes such as CVD, PVD, ALD, HDPCVD, MOCVD, RPCVD, PECVD, LPCVD, ALCVD, APCVD, plating, other suitable methods, or combinations thereof. The spacer layer partially (and, in some embodiments, completely) fills the S/D trenches 519. The spacer deposition process is configured to ensure that the spacer layer fills the air gaps between semiconductor layers 104b and between semiconductor layers 104b and the respective channel regions 102a-102d under gate spacers 111. A spacer etching process is then performed that selectively etches the spacer layer to form inner spacers 116 as depicted in FIG. 4 with minimal (to no) etching of semiconductor layers 104b, dummy gate stacks 109, and gate spacers 111. In the disclosed embodiment, the spacer etching process includes an anisotropic etching, such as plasma etch. The spacer layer (and thus inner spacers 116) includes a material that is different than a material of semiconductor layers 104b and a material of gate spacers 111 to achieve desired etching selectivity during the gate spacer etching process. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the spacer layer includes a low-k dielectric material.

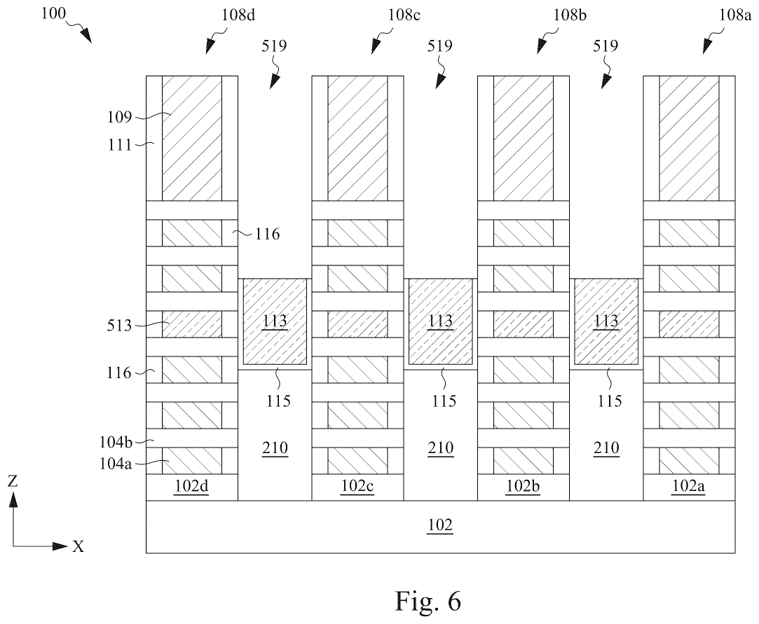

Now referring to FIG. 6, the method 1000 at operation 1010 epitaxially grows first S/D features 210 in the S/D trenches 519 for bottom transistor devices of the CFET device 100. The bottom transistor devices may be PFET transistor devices (or NFET transistor devices). As such, the first source/drain features 210 may include p-type source/drain features that correspond with p-type transistor regions (or alternatively n-type source/drain features that correspond with n-type transistor regions). In the illustrated embodiment, the bottom channels are channel for PFETs, and the first source/drain features 210 are p-type source/drain features. The first source/drain features 210 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of substrate 102 and/or semiconductor stacks 104 (in particular, semiconductor layers 104b). Epitaxial source/drain features are doped with p-type dopants (or n-type dopants). In some embodiments, for the p-type CFET transistors, first epitaxial source/drain features 210 include silicon germanium or germanium and can be doped with boron, other p-type dopant, or combinations thereof (for example, forming Si:Ge:B epitaxial source/drain features). In some embodiments, for the n-type CFET transistors, first epitaxial source/drain features 210 include silicon and can be doped with phosphorous, arsenic, other n-type dopant, or combinations thereof (for example, forming Si:C epitaxial source/drain features, Si:P epitaxial source/drain features, or silicon carbon doped with phosphorus-SiC:P epitaxial source/drain features). In the embodiment shown, the first S/D features 210 are p-type S/D features for PFET devices.

Still referring to FIG. 6, the first S/D features 210 only partially fill the S/D trenches 519. Specifically, they are grown (or grown and recessed) to a height below the channel isolation layer 513 in the z direction. That is, the first S/D features 210 are in direct contact with semiconductor layers 104b for bottom transistor devices under the channel isolation layer 513, but not the semiconductor layers 104b above the channel isolation layer 513. Note that in some embodiments, like as shown, the first S/D features 210 need not be in direct contact with all the semiconductor layers 104b under the channel isolation layer 513. In some embodiments, the first S/D features 210 are formed by a procedure that includes epitaxial growth; performing a chemical mechanical polishing (CMP) process; and etching to selective recess.

Still referring to FIG. 6, the method 1000 at operation 1012 forms an S/D isolation layer 113 over the first S/D features 210. This may be done by first conformably depositing a dielectric liner such as an etch stop layer 115 by CVD, ALD or other suitable processes, then depositing the S/D isolation layer 113 over the etch stop layer 115. An etch process may follow to recess top surfaces of the isolation layer 113 and etch stop layer 115. In some embodiments, the operation 1012 includes depositing the etch stop layer 115 and the isolation layer 113, performing a chemical mechanical polishing (CMP), and etching to recess the deposited materials. In some embodiments, the operation 1012 may apply a selective deposition. The etch stop layer 115 may include silicon nitride and the S/D isolation layer 113 may include a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the S/D isolation layer 113 includes a low-k dielectric material.

The S/D isolation layer 113 only partially fill the S/D trenches 519 since second S/D features 310 are to be formed over the S/D isolation layer 113. However, although only partially filled, the S/D isolation layer 113 should be thick enough to isolate the first S/D features 210 from the later formed second S/D features 310. As such, in some embodiments, like as shown, the S/D isolation layer 113 (or etch stop layer 115) may be in direct contact with sidewalls of the second semiconductor layers 104b, thereby isolating them from contacting the first or second S/D features 210 and 310. The S/D isolation layer 113 has a portion horizontally aligned with the middle layer 107 along the x direction. The S/D isolation layer 113 is separated from the middle layer 107 by inner spacers 116. In an embodiment, the S/D isolation layer 113 has a thickness in the z direction greater than a thickness of the channel isolation layer 513 (or the middle layer 107).

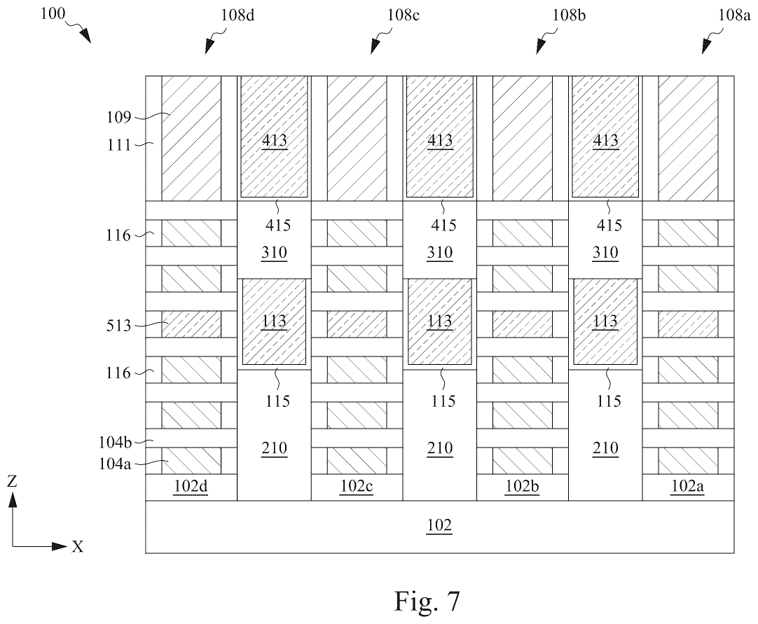

Now referring to FIG. 7, the method 1000 at operation 1014 epitaxially grows second S/D features 310 in the S/D trenches 519 and over the S/D isolation layer 113 for top transistor devices of the CFET device 100. The top transistor devices may be NFET transistor devices (or PFET transistor devices). As such, the second source/drain features 310 may include n-type source/drain features that correspond with n-type transistor regions or p-type source/drain features that correspond with p-type transistor regions. The second source/drain features 310 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of semiconductor stacks 104 (in particular, semiconductor layers 104b). Epitaxial source/drain features are doped with n-type dopants and/or p-type dopants. In some embodiments, for the n-type CFET transistors, second epitaxial source/drain features 310 include silicon and can be doped with phosphorous, arsenic, other n-type dopant, or combinations thereof (for example, forming Si:C epitaxial source/drain features, Si:P epitaxial source/drain features, or silicon carbon doped with phosphorus-SiC:P epitaxial source/drain features). In some embodiments, for the p-type CFET transistors, second epitaxial source/drain features 310 include silicon germanium or germanium and can be doped with boron, other p-type dopant, or combinations thereof (for example, forming Si:Ge:B epitaxial source/drain features). In the embodiment shown, the second S/D features 310 are n-type S/D features for NFET devices.

Still referring to FIG. 7, the second S/D features 310 may completely fill the S/D trenches 519 such that top surfaces of the second S/D features 310 are substantially coplanar with top surfaces of the topmost second semiconductor layers 104b. Alternatively, the second S/D features 310 may grow above the top surfaces of the topmost second semiconductor layers 104b. Note that the second S/D features 310 are in direct contact with semiconductor layers 104b for top transistor devices above the channel isolation layer 513, but not the semiconductor layers 104b below the channel isolation layer 513. Note that in some embodiments, like as shown, the second S/D features 310 need not be in direct contact with all the semiconductor layers 104b above the channel isolation layer 513.

Still referring to FIG. 7, the method 1000 at operation 1016 forms an interlayer dielectric (ILD) layer 413 over the second S/D features 310. This may be done by first conformably depositing a dielectric liner such as an etch stop layer 415 by CVD, ALD or other suitable processes, then depositing the ILD layer 413 over the etch stop layer 415. A planarization process such as CMP may follow to planarize top surfaces of the ILD layer 413, etch stop layer 415, and dummy gate structures 110. The etch stop layer 415 may include silicon nitride and the ILD layer 413 may include a dielectric material that includes for example, silicon oxide, silicon nitride, silicon oxynitride, tetraethoxysilane (TEOS) formed oxide, Phosphosilicate Glass (PSG), Boron-Doped Phosphosilicate Glass (BPSG), low-k dielectric material, other suitable dielectric material, or combinations thereof.

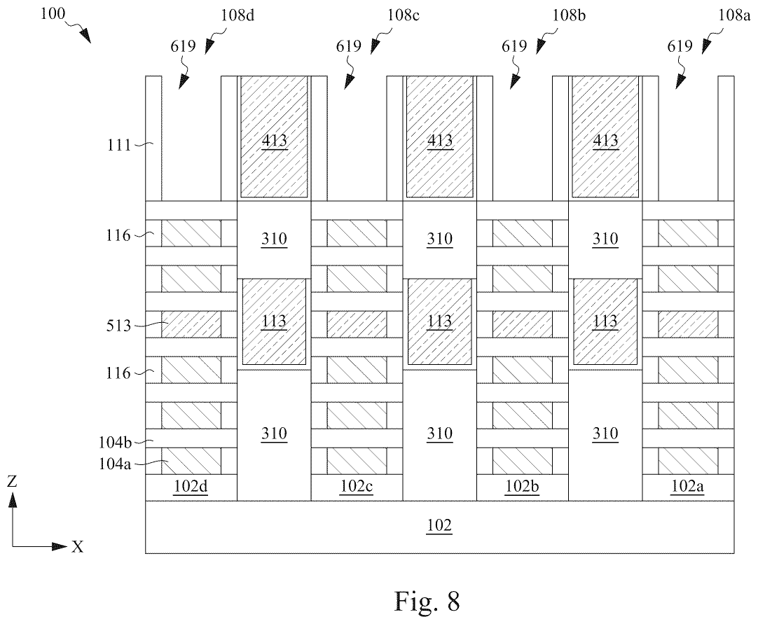

Now referring to FIG. 8, the method 1000 at operation 1018 removes dummy gate stacks 109 from the dummy gate structures 110. The dummy gate stacks 109 are removed by a suitable etching process, thereby resulting in gate trenches 619 and exposing the semiconductor stacks 104. The etching process is designed with an etchant to selectively remove the dummy gate stacks 109. In the depicted embodiment, an etching process completely removes dummy gate stacks 109 to expose surfaces of the semiconductor layers 104a and semiconductor layers 104b in the x-z plane. The etching process is a dry etching process, a wet etching process, other suitable etching process, or combinations thereof. In some embodiments, the etching process is a multi-step etch process. For example, the etching process may include alternative etchants to separately remove various layers of dummy gate stacks 109, such as the dummy gate electrode layers, the dummy gate dielectric layers, and/or the hard mask layers. In some embodiments, the etching process is configured to selectively etch dummy gate stacks 109 with minimal (to no) etching of other features of the IC structure 100, such as ILD layer 413, gate spacers 111, semiconductor layers 104a, and semiconductor layers 104b. In some embodiments, a lithography process is performed to form a patterned mask layer that covers the ILD layer 413 and/or gate spacers 111, and the etching process uses the patterned mask layer as an etch mask.

Still referring to FIG. 8, in an alternative embodiment, the middle layer 107 may be replaced with a channel isolation layer 513 at this stage if not being removed earlier. The middle layer 107 is removed by a suitable etching process. The etching process is designed with an etchant to selectively remove the middle layer 107. As described above, the middle layer 107 has a different concentration of materials such as heavier germanium concentration than other first semiconductor layers 104a (which also include germanium). This allows for selective etching of the middle layer 107 without etching the remaining semiconductor layers 104a. Thereafter, the air void that remains is filled with a dielectric material to form the channel isolation layer 513. The channel isolation layer 513 may include a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the S/D isolation layer 113 includes a low-k dielectric material. In some embodiments, the formation of the channel isolation layer 513 includes etching, deposition, and anisotropic etch, such as plasma etch.

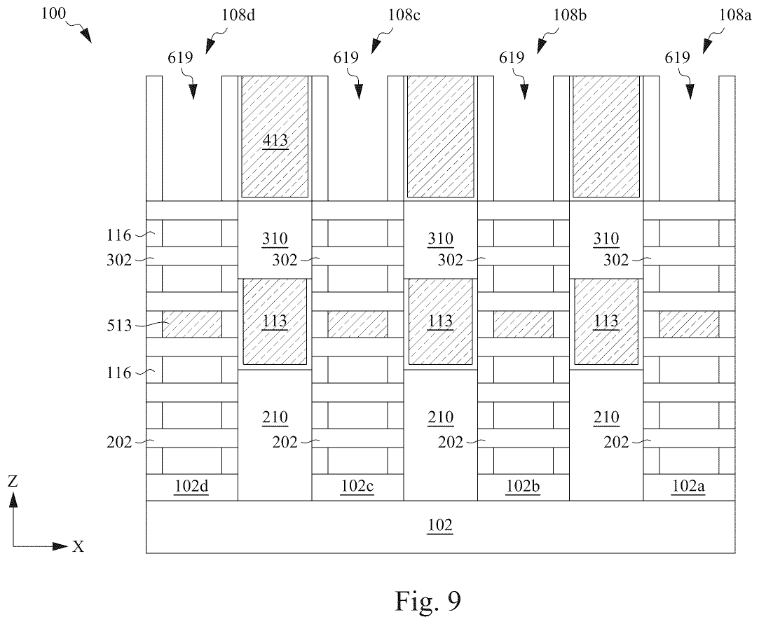

Now referring to FIG. 9, the method 1000 at operation 1022 forms suspended semiconductor channels 202/302 by removing the remaining first semiconductor layers 104a using a suitable etching process. The etching process is designed with an etchant to selectively remove the remaining first semiconductor layers 104a without substantially etching the second semiconductor layers 104b and the channel isolation layer 513. As such, the second semiconductor layers 104b become suspended semiconductor channels 202/302. The suspended semiconductor channels 202 refer to channel layers for the bottom transistor devices (e.g., PFET channels of the CFET device 100) and the suspended semiconductor channels 302 refer to channel layers for the top transistor devices (e.g., NFET channels of the CFET device 100).

Various etching parameters can be tuned such as etchant composition, etching temperature, etching solution concentration, etching time, etching pressure, source power, RF bias voltage, RF bias power, etchant flow rate, other suitable etching parameters, or combinations thereof. The etching process is a dry etching process, a wet etching process, other suitable etching process, or combinations thereof. In some embodiments, a dry etching process (such as an RIE process) utilizes a fluorine-containing gas (for example, SF6) to selectively etch the semiconductor layers. In some embodiments, a ratio of the fluorine-containing gas to an oxygen-containing gas (for example, O2), an etching temperature, and/or an RF power may be tuned to selectively etch silicon germanium (or silicon). In some embodiments, a wet etching process is performed with an etching solution that includes ammonium hydroxide (NH4OH) and water (H2O) to selectively etch the germanium-containing semiconductor layers. In some embodiments, a chemical vapor phase etching process using hydrochloric acid (HCl) is used.

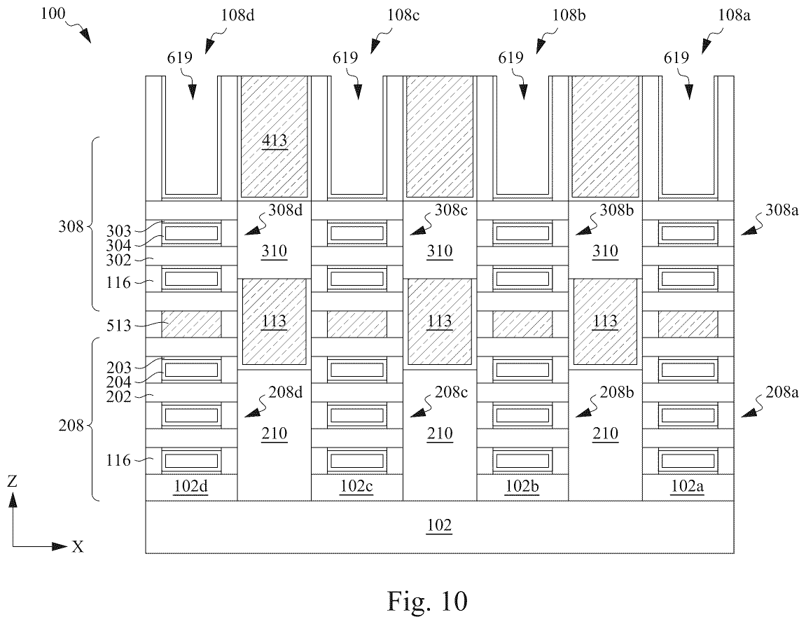

Now referring to FIG. 10, the method 1000 at operation 1024 forms gate dielectric layers over the channel regions 102a-102d and wrapping around each of the suspended semiconductor channels 202/302. The gate dielectric layers 204 partially fills the gaps between the suspended semiconductor channels 202/302 and may include high-k dielectric materials such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TIO, TiO₂, LaO, LaSiO, Ta₂O₃, Ta₂O₅, Y₂O₃, SrTiO₃, BaZrO, BaTiO₃ (BTO), (Ba,Sr)TiO₃ (BST), Si₃N₄, hafnium dioxide-alumina (HfO₂—Al₂O₃) alloy, other suitable high-k dielectric material, or combinations thereof. The gate dielectric layers 205 may be formed by any of the processes described herein, such as ALD, CVD, PVD, oxidation-based deposition process, other suitable process, or combinations thereof. In some embodiments, the high-k dielectric layer 204 includes a thickness ranging between 1 nm and 5 nm. In an embodiment, the gate dielectric layer 205 includes an interfacial layer 203 formed on the channel layers 202/302. The interfacial layer 203 may be formed by thermal oxidation, chemical oxidation, ALD, CVD, or other suitable processes. The interfacial layers 203 may include a dielectric material, such as SiO₂, SiON, other silicon-containing dielectric material, other suitable dielectric material, or combinations thereof. In some embodiments, the interfacial layer 203 includes a thickness ranging between 0.5 nm and 2 nm. The high-k dielectric layer 204 and the interfacial layer 203 are collectively referred to as the gate dielectric layer.

Still referring to FIG. 10, PFET gate regions 208 of the CFET gate regions 108 include interfacial layers 203 directly on top and bottom surfaces of the channel layers 202, and gate dielectric layers 205 directly on top and bottom surfaces of the interfacial layers 203 and on side surfaces of the inner spacers 116. NFET gate regions 308 of the CFET gate regions 108 also include interfacial layers 203 directly on top and bottom surfaces of the channel layers 302, and gate dielectric layers 205 directly on top and bottom surfaces of the interfacial layers 203 and on side surfaces of the inner spacers 116 (and/or the gate spacers 111). In the depicted embodiment, the NFET gate regions 308 are vertically above the PFET gate regions such that NFET devices are formed over PFET devices. However, the present disclosure is not limited thereto. In other embodiments, the PFET gate regions 208 may be above the NFET gate regions 308 such that PFET devices are formed over NFET devices.

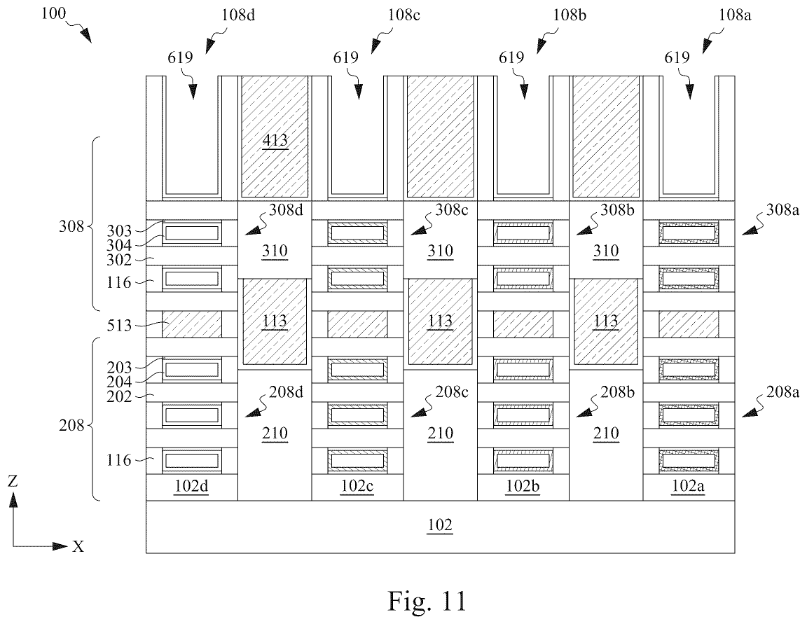

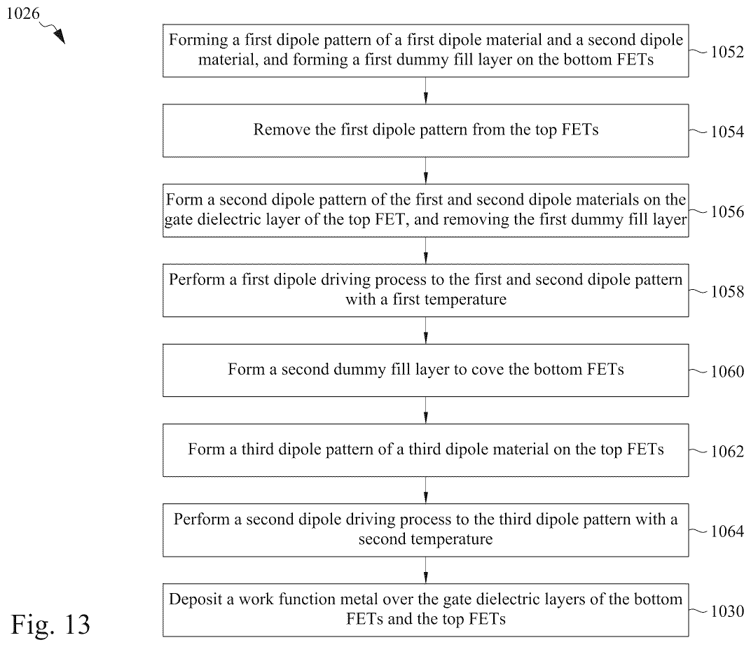

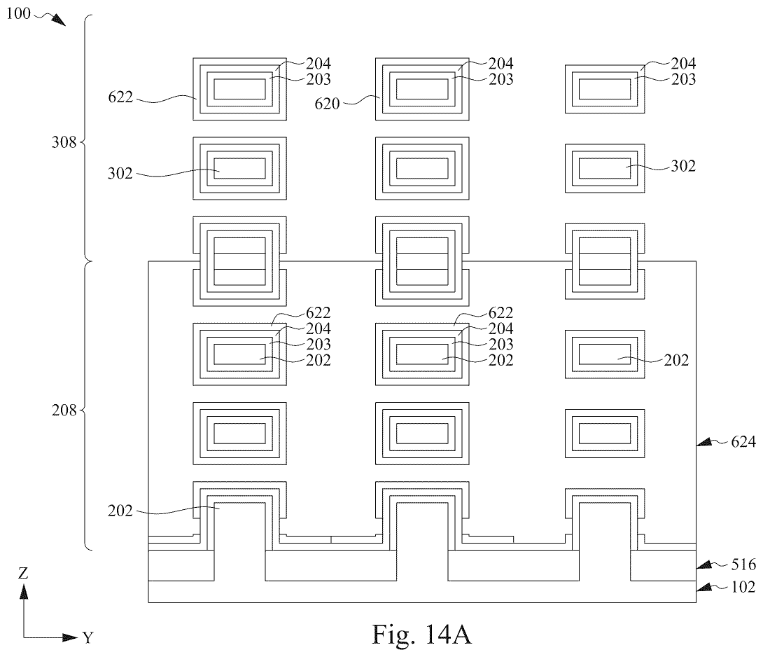

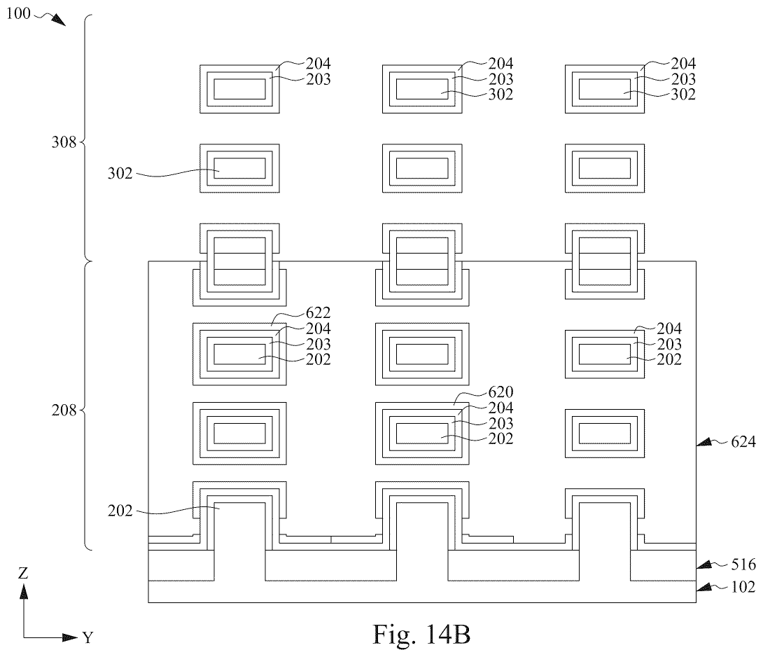

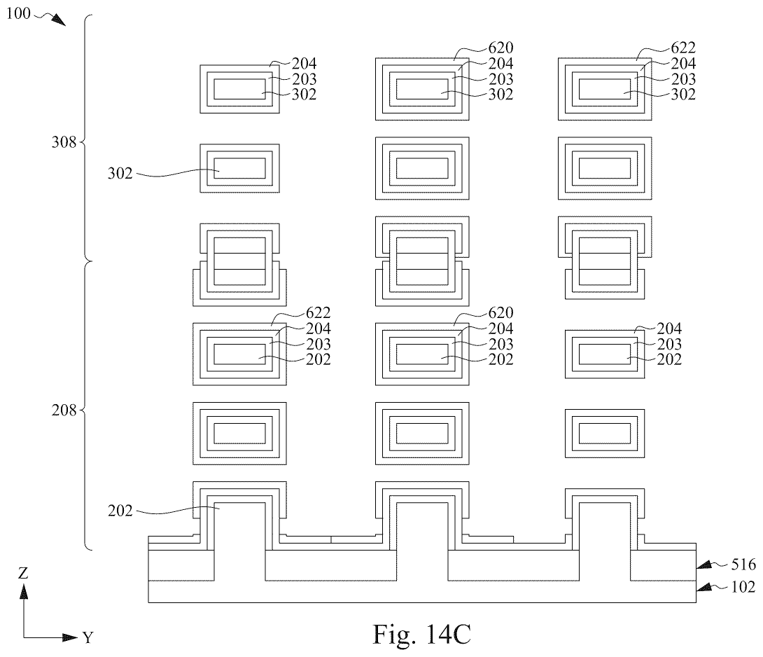

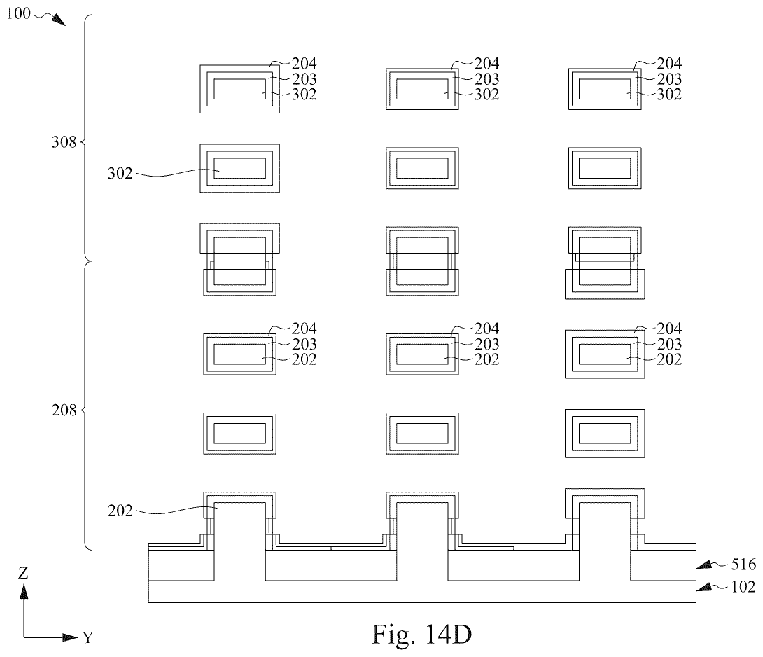

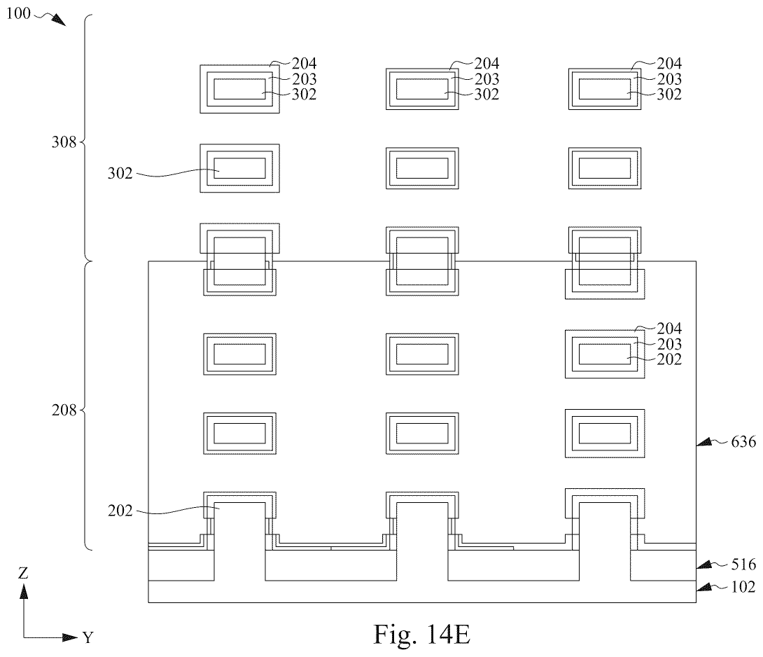

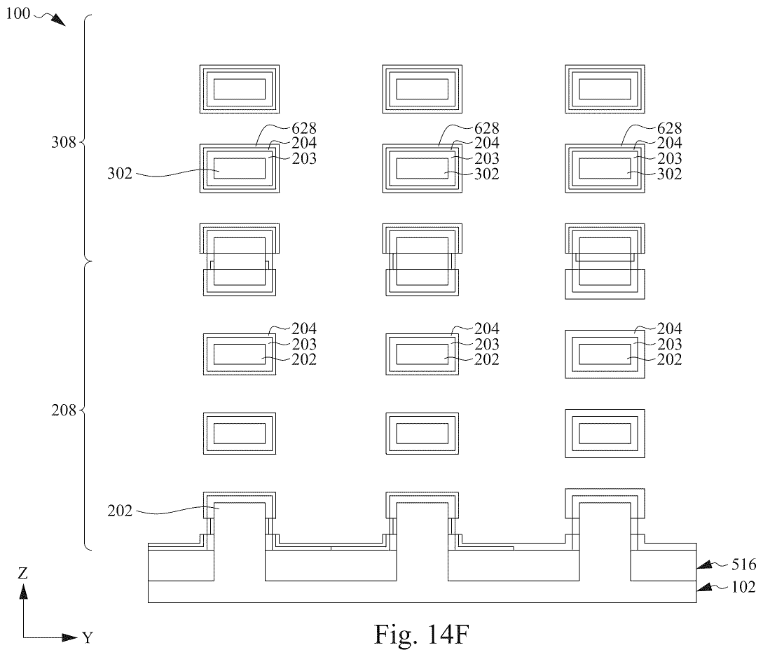

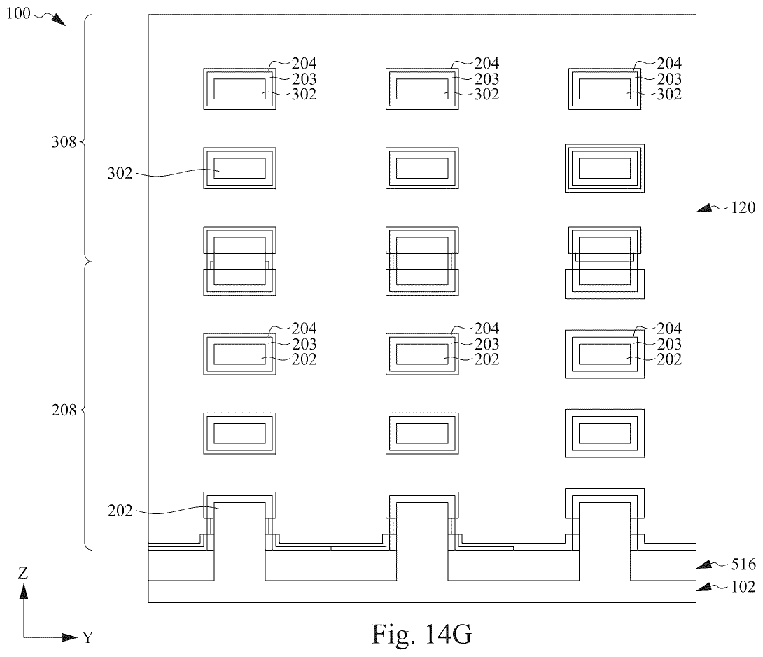

Now referring to FIG. 11, the method 1000 at operation 1026 performs a dipole treatment process to treat the gate dielectric layers, resulting in the gate dielectric layers with various threshold voltages. The dipole treatment process further includes multiples suboperations described below in detail with reference to FIGS. 13 and 14A through 14G. FIG. 13 is a flowchart of the method 1026 constructed according to various embodiments. FIGS. 14A through 14G are sectional views of the IC structure 100, in portion, at various fabrication stages constructed according to some embodiments. In FIGS. 14A through 14G, only three CFETs are illustrated. However, it is not intended to be limiting but for illustration. The IC structure 100 may include as many CFETs as needed in individual applications. Three CFETs include three PFETs and three NFETs stacked on the three PFETs, respectively. Each of those PFETs and NFETs has a different threshold voltage according to its design after the dipole treatment process of the method 1026. For convenience, the three CFETs in FIGS. 14A through 14G are referred to as a first CFET, a second CFET and a third CFET from left to right, respectively. More specifically, three FETs on the bottom portion are referred to as a first bottom CFET, a second bottom CFET and a third bottom CFET from left to right, respectively; and three FETs on the top portion are referred to as a first top CFET, a second top CFET and a third top CFET from left to right, respectively.

Referring to FIGS. 13 and 14A, at an operation 1052 of the method 1026, forming a first dipole pattern on the gate dielectric layer (203 and 204). The first dipole layer includes a first dipole material layer Ma 620 formed on the gate dielectric layer of the second channels for the second CFET, including the second bottom FET (such as PFET) and the second top FET (such as NFET); a second dipole material layer Mb 622 formed on the gate dielectric layer of the first channels for the first CFET, including the first bottom FET (such as PFET) and the first top FET (such as NFET); and none on the gate dielectric layer of the third channels for the third CFET, including the third bottom FET (such as PFET) and the third top FET (such as NFET). The gate dielectric layer includes the interfacial layer 203 and the high-k dielectric layer 204 as described earlier. The first dipole material layer Ma 620 and the second dipole material layer Mb 622 include a same dipole composition but with different dipole concentrations, collectively referred to as a first dipole composition M. In the disclosed embodiment, the first and second dipole material layers Ma and Mb includes a n-type dipole material. In furtherance of the embodiment, the first and second dipole material layers Ma and Mb includes dipole dopant:lanthanum (La) oxide (La₂O₃). In some embodiments, the first and second dipole material layers Ma and Mb includes dipole dopant:lanthanum (La) oxide, yttrium (Y) oxide, erbium (Er), scandium (Sc) oxide, La nitride, Y nitride, Er nitride, Sc nitride, La carbide, Y carbide, Er carbide, Sc carbide, or a combination thereof. In the disclosed embodiment, the first dipole dopant concentration C1 of the first dipole material layer Ma 620 is less than the second dipole dopant concentration C2 of the first dipole material layer Mb 622. In some examples, C1/C2 ranges between 0.2 and 0.8, or alternatively between 0.4 and 0.6. The dipole dopant concentration is defined as atomic percentage.

The formation of the first dipole pattern is formed by deposition and patterning. The patterning further includes deposition and etching or deposition and lift-off process. In some embodiments, the formation method includes depositing a first dipole material layer Ma; patterning the first dipole material layer such that only the portion of the first dipole material layer Ma on the second CFET remain; depositing a second dipole material layer Mb; and patterning the second dipole material layer such that only the portion of the second dipole material layer Mb on the first CFET remain. The patterning process includes forming a photoresist pattern, by a lithography process, with openings to expose the portions to be removed; etching through the opening of the photoresist layer; and removing the photoresist pattern by wet stripping or plasma ashing. In another embodiment, the formation method includes a lift-off process. In furtherance of the embodiment, the formation method includes forming a first photoresist pattern having openings where the first dipole material layer to be formed; depositing a first dipole material layer through the openings of the photoresist pattern; removing the photoresist pattern, thereby lifting off the undesired portions of the first dipole material layer; forming a second photoresist pattern having openings where the second dipole material layer to be formed; depositing a second dipole material layer through the openings of the second photoresist pattern; and removing the photoresist pattern, thereby lifting off the undesired portions of the second dipole material layer.

The operation 1052 further includes forming a first dummy fill material layer 624 to cover the bottom FETs, specifically the gate dielectric layers 205 in the PFET gate regions 208. The first dummy fill layer 624 is a dummy structure and will be removed eventually. In some embodiments, the first dummy fill layer 624 include a bottom anti-reflective coating (BARC) material since it can be formed and removed cost-effectively. It is understood that that dummy fill material may use other suitable material. In the disclosed embodiment, the first dummy fill material layer 624 is formed by spin-on coating or other suitable technique such that it is filled to the level at the channel isolation layer 513. In another embodiment, after spin-on coating, an etching process is applied to the first dummy fill material layer 624 to the level at the channel isolation layer 513. The etching process includes plasma ashing according to some embodiments.

Referring to FIGS. 13 and 14B, at an operation 1054 of the method 1026, an etching process is applied to remove top portion of the first dipole pattern surrounding the gate dielectric layer on the top FETs and exposed by the first dummy fill material layer 624. The etching process applied to the first dipole pattern includes a wet etching process using an etchant having wet etching:hydrochloric acid (HCl) or nitric acid (HNO3) according to some embodiments. Thus, the first dipole pattern is formed on the bottom FETs where the first dipole material layer 620 is surrounding the gate dielectric layer of the second bottom FET; the second dipole material layer 622 is surrounding the gate dielectric layer of the first bottom FET; and none on the gate dielectric layer of the third bottom FET.

Referring to FIGS. 13 and 14C, at an operation 1056 of the method 1026, a second dipole pattern is formed on the gate dielectric layer of the top FETs. Especially, the first dipole material layer Ma 620 is formed on the gate dielectric layer of the second top FET; the second dipole material layer Mb 622 is formed on the gate dielectric layer of the third top FET; and none on the gate dielectric layer of the first top FET. The method to form the second dipole pattern is similar to the method to form the first dipole pattern, such as by a procedure that includes deposition and patterning. Especially, the procedure includes depositing the first dipole material layer; patterning the first dipole material layer such that it remains on the second top FET; depositing the second dipole material layer; patterning the second dipole material layer such that it remains on the third top FET. The similar descriptions are not repeated herein for simplicity. Note that the first dummy fill layer 624 remains during the formation of the second dipole pattern so that the second dipole pattern is not formed on the bottom FETs. After the formation of the second dipole pattern, the first dummy fill layer 624 is removed by a suitable method, such as plasma ashing or wet stripping.

Referring to FIGS. 13 and 14D, at an operation 1058 of the method 1026, a first dipole driving process is applied to drive the dipole dopants from the first dipole pattern and the second dipole pattern into the gate dielectric layer of the bottom and top FETs. The first dipole driving process includes an annealing process at a first temperature T1. In some embodiments, the first temperature T1 is greater than 500° C., such as ranging between 500° C. and 800° C. or ranging between 550° C. and 800° C. After the first driving process, the first and second dipole patterns are removed by a suitable process, such as a wet etching process with an etchant having hydrochloric acid (HCl) or nitric acid (HNO3).

Referring to FIGS. 13 and 14E, at an operation 1060 of the method 1026, a second dummy fill layer 626 is formed to cover the bottom FETs. The second dummy fill layer 626 is similar to the first dummy fill layer 624 and covers the bottom FETs and exposes the top FETs. The formation of the second dummy fill layer 626 is similar to the formation of the first dummy fill layer 624. The similar descriptions are not repeated here.

Referring to FIGS. 13 and 14F, at an operation 1062 of the method 1026, a third dipole pattern is formed on the top FETs while the bottom FETs are covered by the second dummy fill layer 626. Particularly, the third dipole pattern includes a third dipole material layer X 628 (or referred to as a second dipole composition X). The third dipole material layer X 628 includes a dipole composition different from the first and second dipole materials 622, 624. In the present embodiments, the third dipole material layer 628 is also a N-type dipole material. In the disclosed embodiments, the third dipole material layer X 628 includes dipole dopant:strontium (Sr) oxide (SrO). In some embodiments, the first and second dipole material layers Ma and Mb includes dipole dopant:strontium (Sr) oxide, magnesium (Mg) oxide, Sr nitride, Mg nitride, Sr carbide, Mg carbide or a combination thereof. The third dipole material layer is globally deposited on the gate dielectric layer of the top FETs without patterning. After the deposition of the third dipole material layer 628, the second dummy fill layer 626 may be removed at this stage by a suitable method such as plasma ashing.

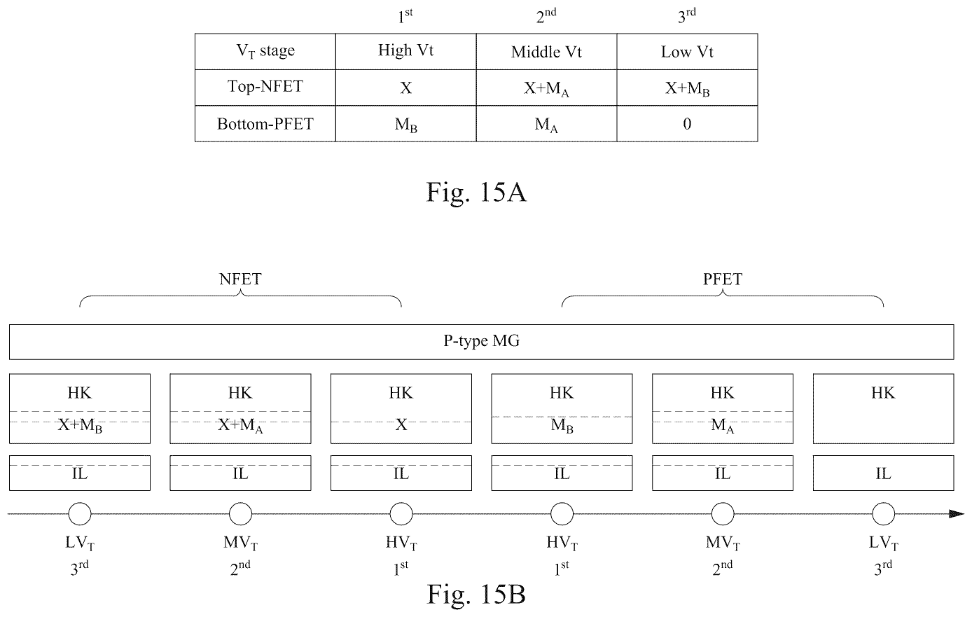

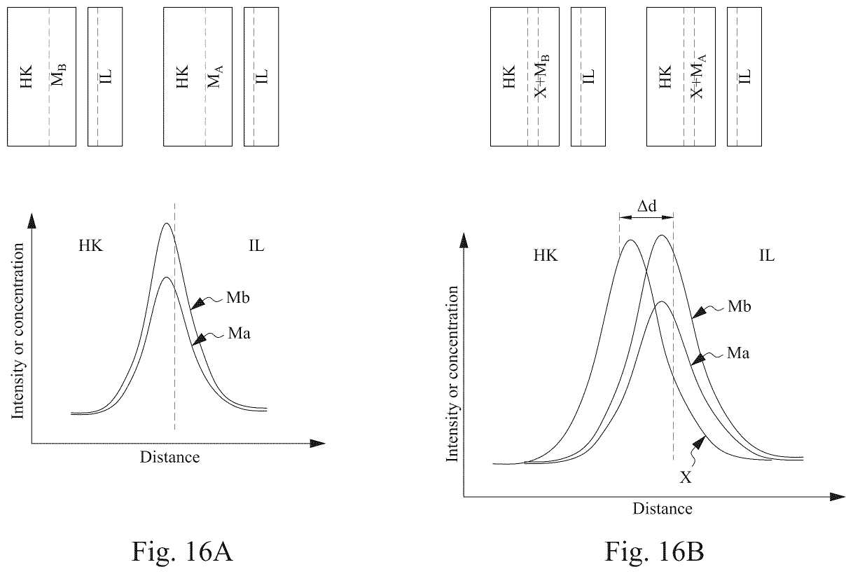

Still referring to FIGS. 13 and 14F, at an operation 1064 of the method 1026, a second dipole driving process is applied to drive the dipole dopants X from the third dipole material layer 628 into the gate dielectric layer of the top FETs. The second dipole driving process includes an annealing process at a second temperature T2 less than T1. In some embodiments, the second temperature T2 is less than 500° C., such as ranging between 400° C. and 500° C. or ranging between 420° C. and 480° C. This is due to the third dipole material layer X 628 is different from the first and second dipole material layers 620, 622 in composition and other factors. For example, the bonding energy of Sr—O in SrO is less than the bonding energy of La—O in La₂O₃, the thermal energy required to break the bonding Sr—O is less than that to break the bonding La—O. After the second driving process, the third dipole material layer X 628 is removed by a suitable process, such as a wet etching process with an etchant having hydrochloric acid (HCl) or nitric acid (HNO3). By the above dipole treatment process, the gate dielectric layer of various top FETs and bottom FETs are treated differently with different dipole compositions and different dipole dopant concentrations, thereby achieve different threshold voltages. This is further illustrated in a table of FIG. 15A. The table illustrates the 1^{st}, the 2^{nd} and 3^{rd} CFETs in FIGS. 14A through 14G, includes the 1^{st}, the 2^{nd} and 3^{rd} bottom PFETs and top NFETs. The table includes various dipole dopant compositions (X and Ma/Mb) and doping concentrations (such as Ma and Mb). Accordingly, the threshold voltages Vt are tuned into high Vt, middle Vt and low Vt of the 1^{st}, the 2^{nd} and 3^{rd} bottom PFETs and top NFETs, respectively. Furthermore, the first dipole dopant composition (Ma and Mb) and the second dipole dopant composition X are distributed with concentration peaks different from each other, which is illustrated in the table of FIG. 15B, with distributions illustrated in FIGS. 16A and 16B. FIG. 16A illustrates the distributions of Ma and Mb in the gate dielectric layer of the bottom PFETs. FIG. 16B illustrates the distributions of Ma, Mb and X in the gate dielectric layer of the top NFETs. Note that the gate dielectric layer includes the interfacial layer 203 on the channels and the high-k dielectric layer 204 on the interfacial layer 203. The horizontal axis shows distance from the high-k dielectric layer 204 from the interfacial layer 203 along the z direction. The vertical axis shows dipole dopant concentration (or intensity).

In the disclosed embodiment, the dipole dopant concentration peaks of the of Ma and Mb in the gate dielectric layer of the bottom PFETs are within the high-k dielectric layer 204 and are near the interface of the interfacial layer 203 and the high-k dielectric layer 204 and but is within the high-k dielectric layer 204. The dipole dopant concentration peaks of the of Ma, Mb and X in the gate dielectric layer of the top PFETs are within the high-k dielectric layer 204 and are near the interface of the interfacial layer 203 and the high-k dielectric layer 204. Particularly, combined Ma and Mb together as one distribution Ma/Mb, the peak distance Δd between the Ma/Mb and X is less than 1 nm. In some embodiment, Δd is ranging between 0.2 nm and 0.8 nm or between 0.4 nm and 0.6 nm.

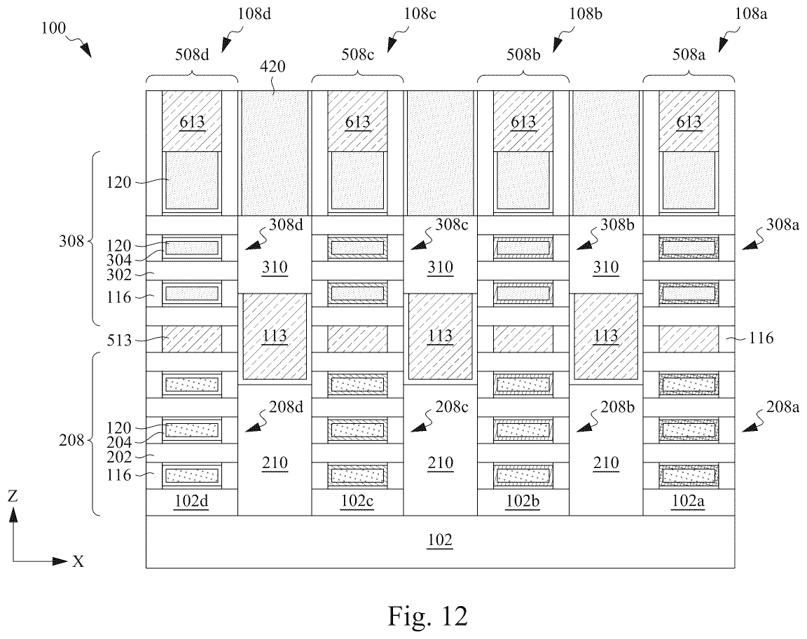

Now referring to FIGS. 13 and 14G and referring back to FIGS. 3B and 12, at an operation 1030, a gate electrode 120 is formed on the gate dielectric layer. Especially, the gate electrodes 120 for both bottom FETs (PFETs in the present embodiment) and the top FETs (NFETs in the present embodiment) include one type of work function metal, which is p-type work function metal includes any suitable p-type work function metal material, such as titanium nitride (TiN), tantalum nitride (TaN), ruthenium (Ru), molybdenum (Mo), tungsten (W), platinum (Pt), titanium (Ti), aluminum (Al), tantalum carbide (TaC), tantalum carbide nitride (TaCN), tantalum silicon nitride (TaSiN), titanium silicon nitride (TiSiN), other suitable materials, or combinations thereof.

The work function metal layer may include one or more material layers of the same or different types (i.e., both n-type work function metal or both p-type work function metal) in order to achieve a desired threshold voltage. The gate electrodes 120 may additionally include fill metal material, such as copper (Cu), tungsten (W), cobalt (Co), ruthenium (Ru), other suitable conductive materials, or combinations thereof. The metal gate structures 508 may include other material layers, such as a barrier layer, a glue layer, and/or a capping layer. The various layers of the gate electrodes 120 may be formed by any suitable method, such as CVD, ALD, PVD, plating, chemical oxidation, thermal oxidation, other suitable methods, or combinations thereof. Thereafter, the method 1000 may perform one or more polishing process (e.g., CMP) to remove any excess conductive materials and planarize the top surface of the IC structure 100.

Referring back to FIGS. 3B and 12, the method 1000 may include other fabrication steps before, during and after the various operations described above. For example, the method 1000 includes forming self-aligned cap 613 on the gate electrode 120. The self-aligned cap 613 includes one or more dielectric material formed by a procedure that further includes selective etching to recess the gate electrodes 120; depositing one or more dielectric material; and performing a CMP process to remove the excessive portions and planarize the top surface. In another example, the method 1000 includes forming an interconnect structure that includes contacts, vias and metal lines. In furtherance of the embodiment, source/drain (S/D) contacts 420 are formed on the source/drain features by a suitable procedure that includes patterning, deposition and CMP.

In the above disclosed embodiment, the dipole materials are N-type dipole material, and the work function metal is P-type work function metal for both bottom PFETs and top NFETs. In an alternative embodiment, the dipole materials are P-type dipole material, which also includes two P-type dipole compositions Ma/Mb and X and with two dipole dopant concentrations Ma and Mb for the first dipole composition, and the work function metal is N-type work function metal for both bottom PFETs and top NFETs. Note that P-type dipole materials are still referred to as Ma, Mb and X. In furtherance of the embodiments, the N-type work function metal includes tantalum (Ta), titanium aluminum (TiAl), titanium aluminum carbide (TiAlC), titanium aluminum oxide (TiAlO), titanium aluminum nitride (TiAlN) or a combination thereof.

The P-type dipole composition Ma/Mb includes aluminum (Al) oxide, vanadium (V) oxide, ruthenium (Ru) oxide, rhodium (Rh) oxide, rhenium (Re) oxide, osmium (Os) oxide, iridium (Ir), aluminum (Al) nitride, vanadium (V) nitride, ruthenium (Ru) nitride, rhodium (Rh) nitride, rhenium (Re) nitride, osmium (Os) nitride, iridium (Ir) oxide, oxide, aluminum (Al) carbide, vanadium (V) carbide, ruthenium (Ru) carbide, rhodium (Rh) carbide, rhenium (Re) carbide, osmium (Os) carbide, iridium (Ir) carbide, or a combination thereof. Note that Ma and Mb include a same composition, but different concentrations as described above in the N-type dipole material Ma/Mn. The P-type dipole composition X includes titanium (Ti) oxide, zinc (Zn) oxide, indium (In) oxide, gallium (Ga) oxide, tantalum (Ta) oxide, tungsten (W) oxide, titanium (Ti) nitride, zinc (Zn) nitride, indium (In) nitride, gallium (Ga) nitride, tantalum (Ta) nitride, tungsten (W) nitride, titanium (Ti) carbide, zinc (Zn) carbide, indium (In) carbide, gallium (Ga) carbide, tantalum (Ta) carbide, tungsten (W) carbide, or a combination thereof.

The formation of the various dipole patterns and the dipole driving processes are similar to those described above with the N-type dipole patterns. Similar descriptions are not repeated herein for simplicity. Similarly, the P-type dipole treatments to the gate dielectric layers and the N-type work function to the gate electrodes of both bottom FETs and the top FETs will achieve various threshold voltages (such as high Vt, middle Vt and low Vt) for both PFETs and NFETs.

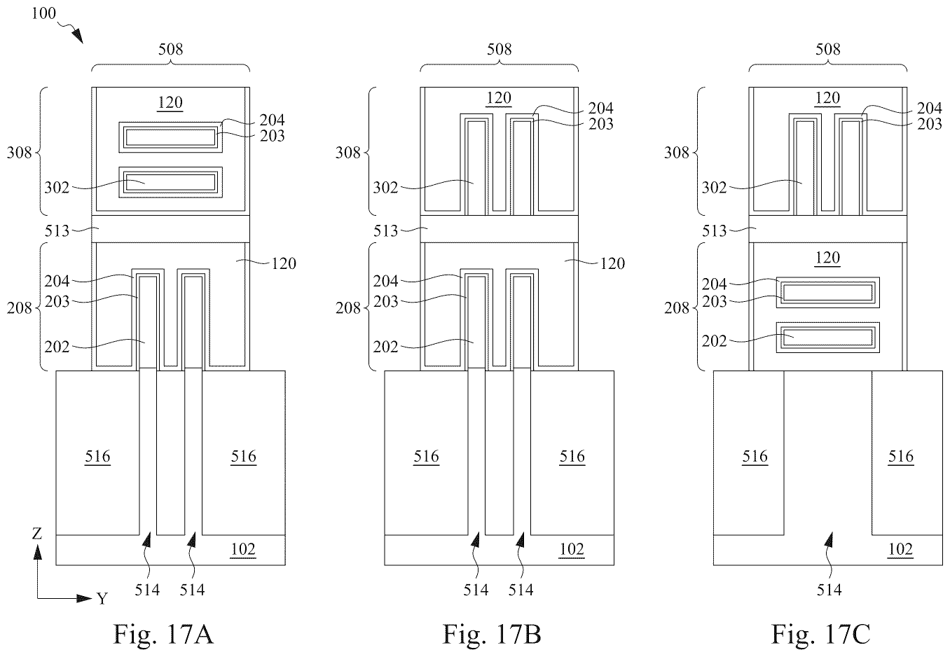

As described above, a CFET structure and the method making the same can effectively form various NFETs and PFETs with various threshold voltages through the disclosed dipole treatments. The CFET structure 100 includes NFETs and PFETs vertically stacked on. The channels 302 of the NFETs and the channels 202 of the PFETs are longitudinally oriented along a horizontal direction, such as along x direction. However, the disclosed method can also be applied to form other CFET structure with various threshold voltages. In some embodiments, the channels 202 of the bottom FETs are vertically oriented and the top channels 302 of the top FETs are horizontally oriented, such as one illustrated in FIG. 17A. The threshold voltages of the bottom FETs and the threshold voltages of the top FETs are tuned differently, as those described above. In some other embodiments, the channels 202 of the bottom FETs are vertically oriented and the top channels 302 of the top FETs are vertically oriented as well, such as one illustrated in FIG. 17B. The threshold voltages of the bottom FETs and the threshold voltages of the top FETs are tuned differently, as those described above. In yet some other embodiments, the channels 202 of the bottom FETs are horizontally oriented and the top channels 302 of the top FETs are vertically oriented, such as one illustrated in FIG. 17A. The threshold voltages of the bottom FETs and the threshold voltages of the top FETs are tuned differently, as those described above.

In various embodiments of the IC structure 100 and the method 1000 making the same, the IC structure 100 includes a CFET structure formed by a monolithic method, therefore being referred to as a monolithic CFET structure, in which both NFETs and PFETs are formed on a same semiconductor substrate. Alternatively, the CFET structure may be formed by a sequential method, in which NFETs and PFETs are formed on different substrates and bonded together, therefore being referred to as sequential CFET structure. The disclosed method of dipole treatment to achieve various threshold voltages can also be used to the sequential CFET structure.

Although not limiting, the present disclosure offers advantages for tuning CFET semiconductor devices to have multiple threshold voltages (Vt). One example advantage is tuning Vt without varying metal gate structure dimensions from one device to another. Instead, dipole loop processes are used to iteratively anneal and remove dopant layers in different gate regions of the CFET device. Another example advantage is that PFET and NFET gate regions in a same CFET may be doped differently to have different materials and different amounts of dopants. Another example advantage is that gate regions within a same NFET or PFET of a CFET may be doped differently from channel to channel, offering different threshold activation voltages for a single NFET or PFET. Another example advantage is the flexibility to vary dopant concentration in different gate regions in a horizontal and a vertical direction of the CFET.

In one example aspect, the present disclosure provides a method that includes providing a substrate; forming active regions on the substrate, wherein the active regions are designed for field-effect transistors (FETs) with different threshold voltages, and wherein the active regions include a plurality of first semiconductor layers of a first semiconductor material and second semiconductor layers of a second semiconductor material alternatively stacked, the second semiconductor material being different from the first semiconductor material in composition; forming a gate dielectric layer on the active regions; forming a first dipole material M patterned on the gate dielectric layer of top FETs and bottom FETs; performing a first dipole process to the gate dielectric layer with a first temperature T1; forming a second dipole material M on the gate dielectric layer on the top FETs and absent from the gate dielectric layer of the bottom FETs;
performing a second dipole process to the gate dielectric layer with a second temperature T2 less than T1 and X being different from M; and filling a work function metal material on the gate dielectric layer of both the bottom FETs and the top FETs.

In another example aspect, the present disclosure provides a method that includes providing a substrate; forming active regions on the substrate, wherein the active regions are designed for field-effect transistors (FETs) with different threshold voltages, and wherein the active regions include a plurality of first semiconductor layers of a first semiconductor material and second semiconductor layers of a second semiconductor material alternatively stacked, the second semiconductor material being different from the first semiconductor material in composition; forming a gate dielectric layer on the active regions; forming a first dipole material M patterned on the gate dielectric layer of top FETs and bottom FETs; performing a first dipole process to the gate dielectric layer with a first temperature T1; forming a second dipole material M on the gate dielectric layer of the top FETs; performing a second dipole process to the gate dielectric layer with a second temperature T2 less than T1 and X being different from M; and filling a work function metal material on the gate dielectric layer of both the bottom FETs and the top FETs, wherein the bottom FETs includes first type FETs and the top FETs includes a second type FETs opposite to the first type FETs.

In yet another example aspect, the present disclosure provides a semiconductor device that includes a first CFET having a first n-type field-effect transistor (NFET) and a first p-type field-effect transistor (PFET) directly below the first NFET, wherein the first NFET has a first NFET channel and a first NFET gate dielectric layer around the first NFET channel, and the first PFET has a first PFET channel and a first PFET gate dielectric layer around the first PFET channel; and a gate metal electrode directly on the first NFET gate dielectric layer and the first PFET gate dielectric layer. The first NFET gate dielectric layer includes a first n-type dipole dopant of a first concentration and a second n-type dipole dopant, and the first PFET gate dielectric layer is free of the first n-type dipole dopant and is free of the second n-type dipole dopant.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method, comprising:
providing a substrate;
forming active regions on the substrate, wherein the active regions are designed for field-effect transistors (FETs) with different threshold voltages, and wherein the active regions include a plurality of first semiconductor layers of a first semiconductor material and second semiconductor layers of a second semiconductor material alternatively stacked, the second semiconductor material being different from the first semiconductor material in composition;
forming a gate dielectric layer on the active regions;
forming a first dipole material M patterned on the gate dielectric layer of top FETs and bottom FETs;
performing a first dipole process to the gate dielectric layer with a first temperature T1;
forming a second dipole material M on the gate dielectric layer on the top FETs and absent from the gate dielectric layer of the bottom FETs;
performing a second dipole process to the gate dielectric layer with a second temperature T2 less than T1 and X being different from M; and
filling a work function metal material on the gate dielectric layer of both the bottom FETs and the top FETs.

2. The method of claim 1, wherein the bottom FETs are P-type FETs (PFETs) and the top FETs are N-type FETs (NFETs) vertically stacked on the PFETs.

3. The method of claim 1, wherein
the first dipole material M includes a first N-type dipole material;
the second dipole material M includes a second N-type dipole material; and
the work function metal material includes a P-type work function metal.

4. The method of claim 3, wherein
the first N-type dipole material includes lanthanum (La) oxide, yttrium (Y) oxide, erbium (Er), scandium (Sc) oxide, La nitride, Y nitride, Er nitride, Sc nitride, La carbide, Y carbide, Er carbide, Sc carbide, or a combination thereof; and
the second N-type dipole material includes strontium (Sr) oxide, magnesium (Mg) oxide, Sr nitride, Mg nitride, Sr carbide, Mg carbide or a combination thereof.

5. The method of claim 3, wherein the P-type work function metal includes titanium nitride (TiN), tantalum nitride (TaN), ruthenium (Ru), molybdenum (Mo), tungsten (W), platinum (Pt), titanium (Ti), aluminum (Al), tantalum carbide (TaC), tantalum carbide nitride (TaCN), tantalum silicon nitride (TaSiN), titanium silicon nitride (TiSiN), other suitable materials, or combinations thereof.

6. The method of claim 1, wherein
the first dipole material M includes a first P-type dipole material;
the second dipole material M includes a second P-type dipole material; and
the work function metal material includes a N-type work function metal.

7. The method of claim 6, wherein
the first P-type dipole material includes aluminum (Al) oxide, vanadium (V) oxide, ruthenium (Ru) oxide, rhodium (Rh) oxide, rhenium (Re) oxide, osmium (Os) oxide, iridium (Ir), aluminum (Al) nitride, vanadium (V) nitride, ruthenium (Ru) nitride, rhodium (Rh) nitride, rhenium (Re) nitride, osmium (Os) nitride, iridium (Ir) oxide, oxide, aluminum (Al) carbide, vanadium (V) carbide, ruthenium (Ru) carbide, rhodium (Rh) carbide, rhenium (Re) carbide, osmium (Os) carbide, iridium (Ir) carbide, or a combination thereof; and
the second P-type dipole material includes titanium (Ti) oxide, zinc (Zn) oxide, indium (In) oxide, gallium (Ga) oxide, tantalum (Ta) oxide, tungsten (W) oxide, titanium (Ti) nitride, zinc (Zn) nitride, indium (In) nitride, gallium (Ga) nitride, tantalum (Ta) nitride, tungsten (W) nitride, titanium (Ti) carbide, zinc (Zn) carbide, indium (In) carbide, gallium (Ga) carbide, tantalum (Ta) carbide, tungsten (W) carbide, or a combination thereof.

8. The method of claim 6, wherein the N-type work function metal includes the N-type work function metal includes tantalum (Ta), titanium aluminum (TiAl), titanium aluminum carbide (TiAlC), titanium aluminum oxide (TiAlO), titanium aluminum nitride (TiAlN) or a combination thereof.

9. The method of claim 1, further comprising forming a fill metal on the work function metal material, wherein the fill metal includes copper (Cu), tungsten (W), cobalt (Co), ruthenium (Ru), other suitable conductive materials, or combinations thereof.

10. The method of claim 1, wherein T1 is greater than 700° C. and T2 is less than 500° C.

11. A method, comprising:
providing a substrate;
forming active regions on the substrate, wherein the active regions are designed for field-effect transistors (FETs) with different threshold voltages, and wherein the active regions include a plurality of first semiconductor layers of a first semiconductor material and second semiconductor layers of a second semiconductor material alternatively stacked, the second semiconductor material being different from the first semiconductor material in composition;
forming a gate dielectric layer on the active regions;
forming a first dipole material M patterned on the gate dielectric layer of top FETs and bottom FETs;
performing a first dipole process to the gate dielectric layer with a first temperature T1;
forming a second dipole material M on the gate dielectric layer of the top FETs;
performing a second dipole process to the gate dielectric layer with a second temperature T2 less than T1 and X being different from M; and
filling a work function metal material on the gate dielectric layer of both the bottom FETs and the top FETs, wherein the bottom FETs includes first type FETs and the top FETs includes a second type FETs opposite to the first type FETs.

12. The method of claim 11, wherein T1 is greater than 700° C. and T2 is less than 500° C.

13. The method of claim 11, wherein the bottom FETs are P-type FETs (PFETs) and the top FETs are N-type FETs (NFETs) vertically stacked on the PFETs.

14. The method of claim 11, wherein
the first dipole material M includes a first N-type dipole material;
the second dipole material M includes a second N-type dipole material; and
the work function metal material includes a P-type work function metal.

15. The method of claim 14, wherein
the first N-type dipole material includes lanthanum (La) oxide, yttrium (Y) oxide, erbium (Er), scandium (Sc) oxide, La nitride, Y nitride, Er nitride, Sc nitride, La carbide, Y carbide, Er carbide, Sc carbide, or a combination thereof;
the second N-type dipole material includes strontium (Sr) oxide, magnesium (Mg) oxide, Sr nitride, Mg nitride, Sr carbide, Mg carbide or a combination thereof; and
the P-type work function metal includes titanium nitride (TiN), tantalum nitride (TaN), ruthenium (Ru), molybdenum (Mo), tungsten (W), platinum (Pt), titanium (Ti), aluminum (Al), tantalum carbide (TaC), tantalum carbide nitride (TaCN), tantalum silicon nitride (TaSiN), titanium silicon nitride (TiSiN), other suitable materials, or combinations thereof.

16. The method of claim 11, wherein
the first dipole material M includes a first P-type dipole material;
the second dipole material M includes a second P-type dipole material; and
the work function metal material includes a N-type work function metal.

17. The method of claim 16, wherein
the first P-type dipole material includes aluminum (Al) oxide, vanadium (V) oxide, ruthenium (Ru) oxide, rhodium (Rh) oxide, rhenium (Re) oxide, osmium (Os) oxide, iridium (Ir), aluminum (Al) nitride, vanadium (V) nitride, ruthenium (Ru) nitride, rhodium (Rh) nitride, rhenium (Re) nitride, osmium (Os) nitride, iridium (Ir) oxide, oxide, aluminum (Al) carbide, vanadium (V) carbide, ruthenium (Ru) carbide, rhodium (Rh) carbide, rhenium (Re) carbide, osmium (Os) carbide, iridium (Ir) carbide, or a combination thereof;
the second P-type dipole material includes titanium (Ti) oxide, zinc (Zn) oxide, indium (In) oxide, gallium (Ga) oxide, tantalum (Ta) oxide, tungsten (W) oxide, titanium (Ti) nitride, zinc (Zn) nitride, indium (In) nitride, gallium (Ga) nitride, tantalum (Ta) nitride, tungsten (W) nitride, titanium (Ti) carbide, zinc (Zn) carbide, indium (In) carbide, gallium (Ga) carbide, tantalum (Ta) carbide, tungsten (W) carbide, or a combination thereof; and
the N-type work function metal includes the N-type work function metal includes tantalum (Ta), titanium aluminum (TiAl), titanium aluminum carbide (TiAlC), titanium aluminum oxide (TiAlO), titanium aluminum nitride (TiAlN) or a combination thereof.

18. A semiconductor device, comprising:
a first CFET having a first n-type field-effect transistor (NFET) and a first p-type field-effect transistor (PFET) directly below the first NFET, wherein the first NFET has a first NFET channel and a first NFET gate dielectric layer around the first NFET channel, and the first PFET has a first PFET channel and a first PFET gate dielectric layer around the first PFET channel; and
a gate metal electrode directly on the first NFET gate dielectric layer and the first PFET gate dielectric layer, wherein
the first NFET gate dielectric layer includes a first n-type dipole dopant of a first concentration and a second n-type dipole dopant, and
the first PFET gate dielectric layer is free of the first n-type dipole dopant and is free of the second n-type dipole dopant.

19. The semiconductor device of claim 18, further comprising:
a second CFET having a second NFET and a second PFET directly below the second NFET, wherein the second NFET has a second NFET channel and a second NFET gate dielectric layer around the second NFET channel, and the second PFET has a second PFET channel and a second PFET gate dielectric layer around the second PFET channel; and
a third CFET having a third NFET and a third PFET directly below the third NFET, wherein the third NFET has a third NFET channel and a third NFET gate dielectric layer around the second NFET channel, and the third PFET has a third PFET channel and a third PFET gate dielectric layer around the third PFET channel, wherein
the gate metal electrode directly on the second and third NFET gate dielectric layers and the second and third PFET gate dielectric layers,
the second NFET gate dielectric layer include the first n-type dipole dopant of a second concentration, and the third NFET gate dielectric layer is free of the first n-type dipole dopant, and each of the first, second and third NFET gate dielectric layers includes the second n-type dipole dopant of a same concentration, and
the second PFET gate dielectric layer includes the first n-type dipole dopant of a third concentration, and the third PFET gate dielectric layer includes the first n-type dipole dopant of a fourth concentration, and the second and third PFET gate dielectric layers are free of the second n-type dipole dopant.

20. The semiconductor device of claim 18, further comprising a P-type work function metal contacting the first, second and third NFET gate dielectric layers, and the first, second and third PFET gate dielectric layers, wherein
the P-type work function metal includes titanium nitride (TiN), tantalum nitride (TaN), ruthenium (Ru), molybdenum (Mo), tungsten (W), platinum (Pt), titanium (Ti), aluminum (Al), tantalum carbide (TaC), tantalum carbide nitride (TaCN), tantalum silicon nitride (TaSiN), titanium silicon nitride (TiSiN), other suitable materials, or combinations thereof,
the first n-type dipole dopant includes lanthanum (La) oxide, and
the second n-type dipole dopant includes strontium (Sr) oxide.
